(19) United States
(12) Patent Application Publication
(10) Pub. No.: US 2026/0182220 A1
(43) Pub. Date: Jun. 25, 2026

(54) DISPLAY DEVICE

(71) Applicant: LG Display Co., Ltd., Seoul (KR)

(72) Inventors: SEONG-IL KIM, Paju-si (KR); WON-RAE KIM, Paju-si (KR); JUNE-HWAN KIM, Paju-si (KR); YOUNG-MIN OH, Paju-si (KR)

(73) Assignee: LG Display Co., Ltd., Seoul (KR)

(21) Appl. No.: 19/393,347

(22) Filed: Nov. 18, 2025

(30) Foreign Application Priority Data
Dec. 23, 2024 (KR) 10-2024-0194309

(51) Int. Cl. H10K 59/80; H10K 59/121; H10K 59/122

(52) U.S. Cl. CPC H10K 59/877; H10K 59/1213; H10K 59/122

(57) ABSTRACT

A display device includes a substrate having a pixel region, a thin film transistor on the substrate and in the pixel region, a planarization layer covering the thin film transistor, a light emitting diode on the planarization layer and in the pixel region, and a pixel definition layer at a boundary of the pixel region. The pixel definition layer has a light-absorbing property, and the planarization layer includes a scattering particle.

### CROSS-REFERENCE TO RELATED APPLICATIONS

The present application claims priority to Korean Patent Application No. 10-2024-0194309, filed in the Republic of Korea on Dec. 23, 2024, the entire disclosure of which is expressly incorporated by reference as if fully set forth herein.

### BACKGROUND

### Field

The present disclosure generally relates to a display device, and more specifically, for example, without limitation, to a display device being capable of preventing a display quality degradation and a current leakage of a thin film transistor and a particle on an anode.

### Discussion of the Related Art

Display devices, such as a television (TV), a monitor, a smartphone, a tablet PC, or a laptop, display images in a variety of formats and forms.

The display device includes a display panel with a plurality of light emitting elements or a liquid crystal for displaying images and transistors for controlling the operation of the light emitting element or the liquid crystal. The display device displays the desired image through the light emitting element or the liquid crystal.

A light emitting display technology, which includes a light emitting diode, is rapidly developing. The light emitting display device can be categorized into an organic light emitting display device, which uses an organic emitting material, and an inorganic light emitting display, which uses an inorganic emitting material.

To reduce or minimize external light reflection (e.g., ambient light reflection), the light emitting display device includes a polarizing plate on the display surface. Recently, various research and development are being conducted to improve the reliability and quality of display devices.

The description provided in the discussion of the related art section should not be assumed to be prior art merely because it is mentioned in or associated with that section. The discussion of the related art section can include information that describes one or more aspects of the subject technology, and the description in this section does not limit the disclosure

### SUMMARY OF THE DISCLOSURE

The present disclosure is directed to a display device that substantially obviates one or more of the problems associated with the limitations and disadvantages of the related art.

An object of the present disclosure is to provide a display device being capable of improving reliability of a pixel definition layer.

An object of the present disclosure is to provide a display device being capable of improving or maintaining an external light reflection property with decreased black particle amount in a pixel definition layer.

An object of the present disclosure is to provide a display device being capable of preventing a current leakage of a thin film transistor with decreased black particle amount in a pixel definition layer.

Additional features and advantages of the present disclosure are set forth in the description which follows, and will be apparent from the description, or evident by practice of the present disclosure. The objectives and other advantages of the present disclosure are realized and attained by the features described herein as well as in the appended drawings.

To achieve these and other advantages in accordance with the purpose of the embodiments of the present disclosure, as described herein, an aspect of the present disclosure is a display device comprising a substrate including a pixel region; a thin film transistor on the substrate and in the pixel region; a planarization layer covering the thin film transistor; a light emitting diode on the planarization layer and in the pixel region; and a pixel definition layer at a boundary of the pixel region, wherein the pixel definition layer has a light-absorbing property, and the planarization layer includes a scattering particle.

It is to be understood that both the foregoing general description and the following detailed description are examples and explanatory and are intended to further explain the present disclosure as claimed.

Other systems, methods, features and advantages will be, or will become, apparent to one with skill in the art upon examination of the following drawings and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

### BRIEF DESCRIPTION OF THE DRAWINGS

The accompanying drawings, which are included to provide a further understanding of the present disclosure and are incorporated in and constitute a part of this specification, illustrate embodiments of the present disclosure and together with the description serve to explain the principles of the present disclosure.

FIG. 1 is a schematic view illustrating an organic light emitting display device according to one or more embodiments of the present disclosure.

FIG. 2 is a schematic circuit diagram of an organic light emitting display device according to one or more embodiments of the present disclosure.

FIG. 3 is a schematic cross-sectional view illustrating an organic light emitting display device according to a first embodiment of the present disclosure.

FIG. 4 is a schematic cross-sectional view illustrating the extinction of light within a planarization layer.

FIG. 5 is a schematic cross-sectional view illustrating an organic light emitting display device according to a second embodiment of the present disclosure.

FIG. 6 is a schematic cross-sectional view illustrating an organic light emitting display device according to a third embodiment of the present disclosure.

FIG. 7 is a schematic an organic light emitting view illustrating a light emitting display device according to a fourth embodiment of the present disclosure.

FIG. 8 is a schematic exploded perspective view of a display module according to an embodiment of the present disclosure.

FIG. 9 is a schematic cross-sectional view of a display module according to an embodiment of the present disclosure.

FIG. 10 is a schematic plan view of a display module according to an embodiment of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to aspects of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations are selected only for convenience of writing the specification and can be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When ‘including’, ‘having’, ‘consisting’, and the like are used in this specification, other parts can be added unless ‘only’ is used. When a component is expressed in the singular, cases including the plural are included unless specific statement is described.

The expression such as “at least one of a, b, and c” described throughout the specification can encompass ‘a alone’, ‘b alone’, ‘c alone’, ‘a and b’, ‘a and c’, ‘b and c’, or ‘all of a, b, and c’. The advantages and features of the present application, and the methods for achieving them, will become apparent by referring to the embodiments described in detail below together with the accompanying drawings.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts can be disposed between the two parts unless a more limiting term, such as “just” or “direct(ly)” is used. Further, the term “can” fully encompasses all the meanings and coverages of the term “may” and vice versa.

In describing a time relationship, for example, when the temporal order is described as, for example, “after,” “subsequent,” “next,” and “before,” a case that is not continuous can be included unless a more limiting term, such as “just,” “immediate(ly),” or “direct(ly)” is used.

The area, length, or thickness of each component described in the specification is illustrated for convenience of explanation, and the present application is not necessarily limited to the area and thickness of the illustrated component.

It will be understood that, although the terms such as “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various aspects of the present disclosure can be partially or overall coupled to or combined with each other, and can be variously inter-operated with each other and driven technically as those skilled in the art can sufficiently understand. The aspects of the present disclosure can be carried out independently from each other, or can be carried out together in co-dependent relationship.

Throughout the drawings and the detailed description, unless otherwise described, the same drawing reference numerals should be understood to refer to the same elements, features, and structures. The relative size and depiction of these elements can be exaggerated for clarity, illustration, and convenience. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations are selected only for convenience of writing the specification and can be thus different from those used in actual products.

Any implementation described herein as an “example” is not necessarily to be construed as preferred or advantageous over other implementations.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term such as “part” or “unit” can apply, for example, to a separate circuit or structure, an integrated circuit, a computational block of a circuit device, or any structure configured to perform a described function as should be understood to one of ordinary skill in the art.

Without specific description, a transistor constituting the pixel circuit of the present disclosure can include at least one of an oxide thin film transistor (Oxide TFT), an amorphous silicon TFT (a-Si TFT), and a low temperature poly silicon (LTPS) TFT.

The following embodiments are described with reference to organic light emitting display devices. However, the embodiment of the present disclosure is not limited to organic light emitting display devices. For example, a display device according to an embodiment of the present disclosure can be an organic light emitting display device using an organic light emitting material, an inorganic light emitting display device using an inorganic light emitting material such as a quantum dot, or a micro-light emitting diode (LED) display device. Namely, the light emitting diode display device of the present disclosure can be an organic light emitting display device, an inorganic light emitting display device, or a micro-LED display device.

Reference will now be made in detail to some of the examples and embodiments of the present disclosure, which are illustrated in the accompanying drawings. All the components of each display device/apparatus according to all embodiments of the present disclosure are operatively coupled and configured.

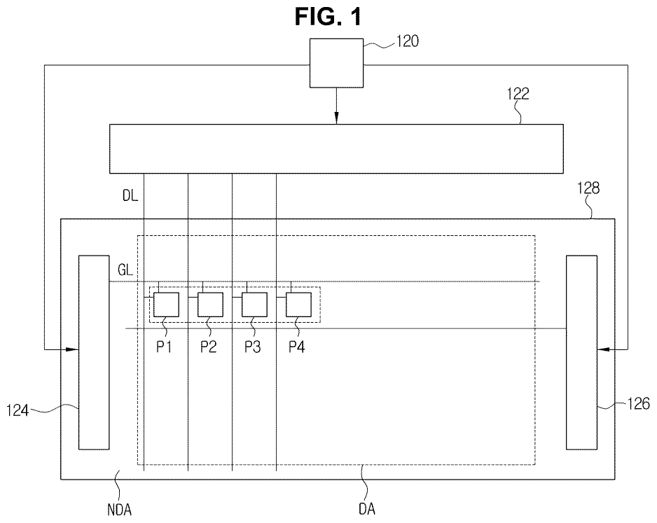

FIG. 1 is a schematic view illustrating an organic light emitting display device according to one or more embodiments of the present disclosure.

As shown in FIG. 1, an organic light emitting display device according to an embodiment of the present disclosure includes a timing controlling unit 120 (e.g., a circuit), a data driving unit 122 (e.g., a circuit), first and second gate driving units 124 and 126 (e.g., circuits) and a display panel 128.

The timing controlling unit 120 generates an image data RGB, a data control signal and a gate control signal using an image signal and a plurality of timing signals including a data enable signal, a horizontal synchronization signal, a vertical synchronization signal and a clock signal transmitted from an external system such as a graphic card or a television system. The timing controlling unit 120 transmits the image data and the data control signal to the data driving unit 122, and transmits the gate control signal to the first and second gate driving units 124 and 126.

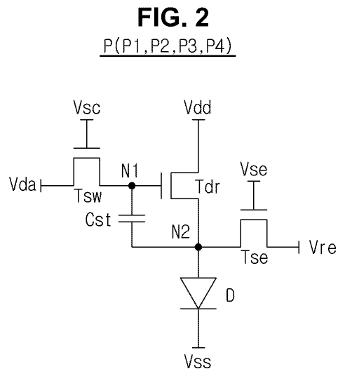

The data driving unit 122 generates a data signal (a data voltage) Vda (of FIG. 2) using the image data and the data control signal transmitted from the timing controlling unit 120 and transmits the data signal Vda to a data line DL of the display panel 128.

The first and second gate driving units 124 and 126 generate a gate signal (a gate voltage) Vsc and Vse (of FIG. 2) using the gate control signal transmitted from the timing controlling unit 120 and applies the gate signal Vsc and Vse to a gate line GL of the display panel 128.

The first and second gate driving units 124 and 126 can have a gate in panel (GIP) type to be formed in a non-display area NDA of a substrate of the display panel 128 having the gate line GL, the data line DL and a pixel region P.

Although the first and second gate driving units 124 and 126 are disposed in both side portions of the display panel 128 in the embodiment of FIG. 1, one gate driving unit can be disposed in one side portion of the display panel 128 in another embodiment.

The display panel 128 includes a display area DA at a central portion thereof and a non-display area NDA surrounding the display area DA. The display panel 128 displays an image using the gate signal Vsc and Vse and the data signal Vda. For displaying an image, the display panel 128 includes a plurality of pixel regions P, a plurality of gate lines GL and a plurality of data lines DL in the display area DA.

The gate line GL and the data line DL cross each other to define the first, second, third and fourth pixel regions P1, P2, P3 and P4. For example, the first, second, third and fourth pixel regions P1, P2, P3 and P4 and SP4 can correspond to red, green, blue and white colors, respectively.

Each of the first, second, third and fourth pixel regions P1, P2, P3 and P4 can include a plurality of transistors such as a switching transistor Tsw (of FIG. 2), a driving transistor Tdr (of FIG. 2) and a sensing transistor Tse (of FIG. 2), a storage capacitor Cst (of FIG. 2) and a light emitting diode D (of FIG. 2).

FIG. 2 is a schematic circuit diagram of an organic light emitting display device according to one or more embodiments of the present disclosure.

Referring to FIG. 2 with FIG. 1, each of the first, second, third and fourth pixel regions P1, P2, P3 and P4 of the light emitting display device according to an embodiment of the present disclosure includes a switching transistor Tsw, a driving transistor Tdr, a sensing transistor Tse, a storage capacitor Cst and a light emitting diode D.

Although each of the first, second, third and fourth pixel regions P1, P2, P3 and P4 has a 3T1C structure having three transistors and one storage capacitor in the embodiment of FIG. 2, each of the first, second, third and fourth pixel regions P1, P2, P3 and P4 can have one of a 6T1C structure having six transistors and one storage capacitor, a 7T1C structure having seven transistors and one storage capacitor and a 8T1C structure having eight transistors and one storage capacitor in another embodiment.

Although the switching transistor Tsw, the driving transistor Tdr and the sensing transistor Tse can have a negative type in the embodiment of FIG. 2, at least one of the switching transistor Tsw, the driving transistor Tdr and the sensing transistor Tse can have a positive type in another embodiment.

The switching transistor Tsw is switched according to a scan signal Vsc to transmit a data signal Vda to a first node N1.

A gate electrode of the switching transistor Tsw is connected to the gate line GL to receive the scan signal Vsc, a drain electrode of the switching transistor Tsw is connected to the data line DL to receive the data signal Vda, and a source electrode of the switching transistor Tsw is connected to the first node N1.

The driving transistor Tdr is switched according to a voltage of the first node N1 to transmit a high level signal (high level voltage) Vdd to a second node N2.

A gate electrode of the driving transistor Tdr is connected to the first node N1, a drain electrode of the driving transistor Tdr is connected to a high level power line to receive the high level signal Vdd, and a source electrode of the driving transistor Tdr is connected to the second node N2.

The sensing transistor Tse is switched according to a sensing signal (sensing voltage) Vse to transmit a reference signal (reference voltage) Vre to the second node N2 or transmit a voltage of the second node N3 to a reference line.

A gate electrode of the sensing transistor Tse is connected to the gate line GL to receive the sensing signal Vse, a drain electrode of the sensing transistor Tse is connected to the reference line to receive the reference signal Vre or transmit a voltage of the second node N2 to the reference line, and a source electrode of the sensing transistor Tse is connected to the second node N2.

The storage capacitor Cst keeps the data signal Vda supplied to the first node N1 for one frame and stores a threshold voltage Vth of the driving transistor Tdr.

A first capacitor electrode of the storage capacitor Cst is connected to the first node N1, and a second capacitor electrode of the storage capacitor Cst is connected to the second node N2.

The light emitting diode D emits a light of a luminance proportional to a current of the driving transistor Tdr.

An anode of the light emitting diode D is connected to the second node N2, and a cathode of the light emitting diode D is connected to a low level power line to receive a low level signal (low level voltage) Vss.

The source electrode of the switching transistor Tsw, the gate electrode of the driving transistor Tdr and the first capacitor electrode of the storage capacitor Cst constitute the first node N1, and the source electrode of the driving transistor Tdr, the source electrode of the sensing transistor Tse, the second capacitor electrode of the storage capacitor Cst and anode of the light emitting diode D constitute the second node N2.

The light emitting diode D can display an image having a luminance corresponding to the image data RGB according to a driving of pixel circuits of the first, second, third and fourth pixel regions P1, P2, P3 and P4.

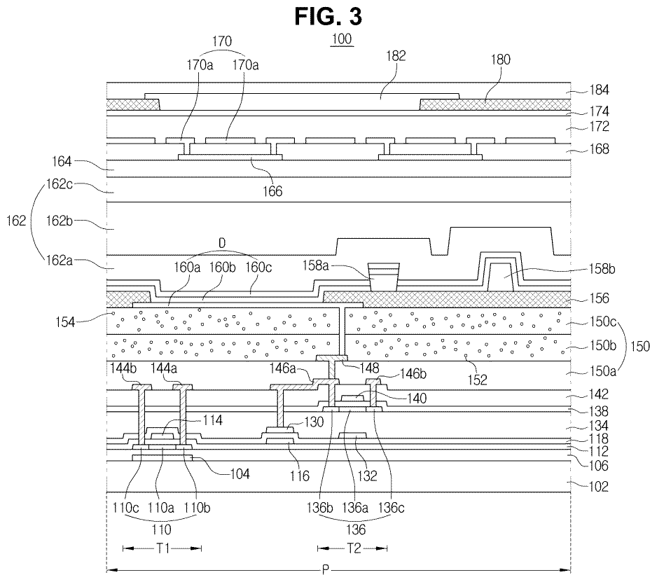

FIG. 3 is a schematic cross-sectional view illustrating an organic light emitting display device according to a first embodiment of the present disclosure.

As shown in FIG. 3, the organic light emitting display device 100 includes a substrate 102, a thin film transistor (TFT) on the substrate 102, a planarization layer 150 covering the TFT, an organic light emitting diode (OLED) D on the planarization layer 150 and a pixel definition layer (e.g., a bank) 156 on the planarization layer 150 and at a boundary of a pixel region P.

A plurality of pixel regions P are defined on the substrate 102. The substrate 102 can be a glass substrate or a plastic substrate. For example, the substrate 102 can be one of a polyimide (PI) substrate, a polyethersulfone (PES) substrate, a polyethylenenaphthalate (PEN) substrate, a polyethylene terephthalate (PET) substrate and a polycarbonate (PC) substrate.

In an embodiment of the present disclosure, the substrate 102 can have a triple-layered structure including a first polyimide (PI) layer, a second PI layer and an interlayer inorganic layer between the first and second PI layers.

A first light shielding pattern 104 is disposed on the substrate 102. The light through the substrate 102 can be blocked by the first light shielding pattern 104. For example, the first light shielding pattern 104 can be formed of a metallic material, e.g., molybdenum (Mo), aluminum (Al), chromium (Cr), gold (Au), titanium (Ti), nickel (Ni), neodymium (Nd), copper (Cu) or their alloy, and have a single-layered structure or a multi-layered structure.

A first buffer layer 106 covering the first light shielding pattern 104 is disposed over the substrate 102. The moisture and/or oxygen can be blocked by the first buffer layer 106. For example, the first buffer layer 106 can be formed of an inorganic insulating material, e.g., silicon oxide or silicon nitride, and have a single-layered structure or a multi-layered structure. When the first light shielding pattern 104 is omitted, the first buffer layer 106 can be directly formed on the substrate 102 and contact the substrate 102.

A first semiconductor layer 110 corresponding to the first light shielding pattern 104 is disposed on the first buffer layer 106. The first semiconductor layer 110 can include one of a poly-semiconductor material, an amorphous semiconductor material and an oxide semiconductor material. When the first light shielding pattern 104 and the first buffer layer 106 are omitted, the first semiconductor layer 110 can be directly disposed on the substrate 102.

In an example embodiment of the present disclosure, the first semiconductor layer 110 can be formed of a poly-semiconductor material, e.g., polycrystalline silicon. The first semiconductor layer 110 can include a first channel region 110a, a first source region 110b at one side of the first channel region 110a and a first drain region 110c at the other side of the first channel region 110a. Impurities can be dopped into the first source and drain regions 110b and 110c.

A first gate insulating layer 112 covering the first semiconductor layer 110 is disposed over the first buffer layer 106. The first gate insulating layer 112 can be formed of an inorganic insulating material, e.g., silicon oxide or silicon nitride, and have a single-layered structure or a multi-layered structure.

A first gate electrode 114 corresponding to the first channel region 110a of the first semiconductor layer 110 is disposed on the first gate insulating layer 112. In addition, a first capacitor electrode 116, which is spaced apart from the first gate electrode 114, is disposed on the first gate insulating layer 112.

The first gate electrode 114 and the first capacitor electrode 116 can be disposed on the same or substantially same layer and be formed of the same or substantially same material. For example, each of the first gate electrode 114 and the first capacitor electrode 116 can be formed of a metallic material, e.g., Mo, Al, Cr, Au, Ti, Ni, Nd, Cu or their alloy, and have a single-layered structure or a multi-layered structure.

A first interlayer insulating layer 118 covering the first gate electrode 114 and the first capacitor electrode 116 is disposed on the first gate insulating layer 112. The first interlayer insulating layer 118 can be formed of an inorganic insulating material, e.g., silicon oxide or silicon nitride, and have a single-layered structure or a multi-layered structure.

A second capacitor electrode 130 corresponding to the first capacitor electrode 116 and a second light shielding pattern 132 spaced apart from the second capacitor electrode 130 are disposed on the first interlayer insulating layer 118.

The second capacitor electrode 130 and the second light shielding pattern 132 can be disposed on the same or substantially same layer and be formed of the same or substantially same material. For example, each of the second capacitor electrode 130 and the second light shielding pattern 132 can be formed of a metallic material, e.g., Mo, Al, Cr, Au, Ti, Ni, Nd, Cu or their alloy, and have a single-layered structure or a multi-layered structure.

A second interlayer insulating layer 134 covering the first second capacitor electrode 130 and the second light shielding pattern 132 is disposed on the first interlayer insulating layer 118. The external moisture and/or oxygen can be blocked by the second interlayer insulating layer 134. For example, the second interlayer insulating layer 134 can be formed of an inorganic insulating material, e.g., silicon oxide or silicon nitride, or an organic insulating material, e.g., photo-acryl or benzocyclobutene (BCB), and have a single-layered structure or a multi-layered structure.

A second semiconductor layer 136 corresponding to the second light shielding pattern 132 is disposed on the second interlayer insulating layer 134. The second semiconductor layer 136 can include one of a poly-semiconductor material, an amorphous semiconductor material and an oxide semiconductor material.

In an example embodiment of the present disclosure, the second semiconductor layer 136 can be formed of an oxide semiconductor material, e.g., indium-gallium-zinc oxide (IGZO), zinc oxide (ZnO), tin oxide (SnO2), copper oxide (Cu2O), nickel oxide (NiO), indium-tin-zinc oxide (ITZO) or indium-aluminum-zinc oxide (IAZO).

The second semiconductor layer 136 can include a second channel region 136a, a second source region 136b at one side of the second channel region 136a and a second drain region 136c at the other side of the second channel region 136a. Impurities can be dopped into the second source and drain regions 136b and 136c.

A second gate insulating layer 138 covering the second semiconductor layer 136 is disposed over the second interlayer insulating layer 134. The second gate insulating layer 138 can be formed of an inorganic insulating material, e.g., silicon oxide or silicon nitride, and have a single-layered structure or a multi-layered structure.

A second gate electrode 140 corresponding to the second channel region 136a of the second semiconductor layer 136 is disposed on the second gate insulating layer 138. For example, the second gate electrode 140 can be formed of a metallic material, e.g., Mo, Al, Cr, Au, Ti, Ni, Nd, Cu or their alloy, and have a single-layered structure or a multi-layered structure.

A third interlayer insulating layer 142 covering the second gate electrode 140 is disposed on the second gate insulating layer 138. The third interlayer insulating layer 142 can be formed of an inorganic insulating material, e.g., silicon oxide or silicon nitride, and have a single-layered structure or a multi-layered structure.

A first source electrode 144a, a first drain electrode 144b, a second source electrode 146a and a second drain electrode 146b are disposed on the third interlayer insulating layer 142.

The first source electrode 144a and the first drain electrode 144b are respectively connected to the first source region 110b and the first drain region 110c via contact holes through the third interlayer insulating layer 142, the second gate insulating layer 138, the second interlayer insulating layer 134, the first interlayer insulating layer 118 and the first gate insulating layer 112. The first source electrode 144a is connected to the first capacitor electrode 116 via a contact hole through the third interlayer insulating layer 142, the second gate insulating layer 138, the second interlayer insulating layer 134 and the first interlayer insulating layer 118.

The second source electrode 146a and the second drain electrode 146b are respectively connected to the second source region 136b and the second drain region 136c via contact holes through the third interlayer insulating layer 142 and the second gate insulating layer 138. The second source electrode 146a is connected to the second capacitor electrode 130 via a contact hole through the third interlayer insulating layer 142, the second gate insulating layer 138 and the second interlayer insulating layer 134.

The first source and drain electrodes 144a and 144b and the second source and drain electrodes 146a and 146b can be disposed on the same or substantially same layer and formed of the same or substantially same material. For example, each of the first source and drain electrodes 144a and 144b and the second source and drain electrodes 146a and 146b can be formed of a metallic material, e.g., Mo, Al, Cr, Au, Ti, Ni, Nd, Cu or their alloy, and have a single-layered structure or a multi-layered structure.

The first semiconductor layer 110, the first gate electrode 114, the first source electrode 144a and the first drain electrode 144b constitute a first TFT T1, and the second semiconductor layer 136, the second gate electrode 140, the second source electrode 146a and the second drain electrode 146b constitute a second TFT T2. For example, the first TFT T1 can be a switching TFT, and the second TFT can be a driving TFT. In addition, the first and second capacitor electrodes 116 and 130 constitute a storage capacitor.

The organic light emitting display device of the present disclosure includes the first and second TFTs T1 and T2. Each of the first semiconductor layer 110 of the first TFT T1 and the second semiconductor layer 136 of the second TFT T2 can include one of a poly-semiconductor material, an amorphous semiconductor material and an oxide semiconductor material, and at least one of the first semiconductor layer 110 of the first TFT T1 and the second semiconductor layer 136 of the second TFT T2 can include the oxide semiconductor material. In an example embodiment of the present disclosure, the first semiconductor layer 110 of the first TFT T1 can be formed of the poly-semiconductor material, e.g., polycrystalline silicon, and the second semiconductor layer 136 of the second TFT T2 can be formed of the oxide semiconductor material.

In FIG. 3, the first gate electrode 114, the first source electrode 144a and first drain electrode 146a are disposed over the first semiconductor layer 110, and the second gate electrode 140, the second source electrode 146a and the second drain electrode 146b are disposed over the second semiconductor layer 136. Namely, each of the first and second TFTs T1 and T2 has a coplanar structure. Alternatively, in each of the first and second TFTs T1 and T2, a gate electrode can be disposed under a semiconductor layer, and a source and a drain electrode can be disposed over the semiconductor layer. Namely, each of the TFTs T1 and T2 can have an inverted-staggered structure.

A planarization layer 150 covering the first source and drain electrodes 144a and 144b and the second source and drain electrodes 146a and 146b is disposed on the third interlayer insulating layer 142. The planarization layer 150 can be formed of an organic insulating material, e.g., photo-aryl or BCB.

The planarization layer 150 can include a first planarization layer 150a on the first source and drain electrodes 144a and 144b and the second source and drain electrodes 146a and 146b, a second planarization layer 150b on the first planarization layer 150a and a third planarization layer 150c on the second planarization layer 150b.

A connection electrode 148 corresponding to the second source electrode 146a is disposed on the first planarization layer 150a. The connection electrode 148 can connected to the second source electrode 146a through a contact hole in the first planarization layer 150a. For example, the connection electrode 148 can be formed of a metallic material, e.g., Mo, Al, Cr, Au, Ti, Ni, Nd, Cu or their alloy, and have a single-layered structure or a multi-layered structure.

The second planarization layer 150b is disposed on the first planarization layer 150a to cover the connection electrode 148, and the third planarization layer 150c is disposed on the second planarization layer 150b. A flatness of an anode 160a of the OLED D can be degraded by a step difference resulting from an electrode or a signal line under the anode 160a so that there can be a problem, e.g., a lifespan decrease of the OLED D. However, in the organic light emitting display device 100 of the present disclosure, the step difference can be compensated by the third planarization layer 160c so that the above problem can be prevented.

In FIG. 3, the planarization layer 150 includes the first to third planarization layers 150a, 150b and 150c to have a triple-layered structure. In an embodiment of the present disclosure, the connection electrode 148 and the first planarization layer 150a can be omitted so that the planarization layer 150 can have a double-layered structure. In an embodiment of the present disclosure, additional planarization layer can be further disposed so that the planarization layer 150 can have four or more layers.

The planarization layer 150 includes a scattering particle. For example, in the planarization layer 150, the scattering particle can be dispersed in an organic insulating material.

In an embodiment of the present disclosure, at least one of the first to third planarization layers 150a, 150b and 150c can include the scattering particle. For example, the second planarization layer 150b can include a first scattering particle 152, and the third planarization layer 150c can include a second scattering particle 154.

Each of the first and second scattering particles 152 and 154 can be formed of an inorganic material, e.g., silicon oxide (SiO2), or an organic material, e.g., polyoxyethylene, polyoxyethylene glycol, polyoxypropylene alkyl ether, polyoxypropylene monoalkyl ether, polyoxypropylene alkyl, polyoxyethylene tallowamine, polyoxyethylene oleylamine, polyoxyethylene sterylamine, polyoxyethylene laurylamine, polyoxyethylene sorbitan ester, polyoxyethylene octyl ether, polyoxyethylene glycerin ether, polyacrylic acid, polysulfonic acid, polyacrylic amine, triethylene amine, their copolymer or their blocked-copolymer.

Each of the first and second scattering particles 152 and 154 can have a diameter (e.g., a size) in a range of 1 nm to 80 nm or in a range of 100 nm to 1000 nm. For example, each of the first and second scattering particles 152 and 154 can have a diameter in a range of 10 nm to 80 nm or in a range of 300 nm to 700 nm. When each of the first and second scattering particles 152 and 154 has a diameter in a range of 1 nm to 80 nm, a Rayleigh scattering can occur by each of the first and second scattering particles 152 and 154. Alternatively, when each of the first and second scattering particles 152 and 154 has a diameter in a range of 100 nm to 1000 nm, a Mie scattering can occur by each of the first and second scattering particles 152 and 154.

In FIG. 3, the planarization layer 150 includes the first to third planarization layer 150a, 150b and 150c, and the second and third planarization layers 150b and 150c respectively include the first and second scattering particles 152 and 154. In an embodiment of the present disclosure, the first planarization layer 150a also includes a scattering particle. The scattering particle in the first planarization layer 150a can have the diameter as the first and second scattering particles 152 and 154.

A first electrode 160a is disposed on the second planarization layer 150b. The first electrode 160a corresponds to the connection electrode 148 and is connected to the connection electrode 148 through a contact hole in the second and third planarization layers 150b and 150c.

For example, the first electrode 160a is separately formed in each pixel region P. The first electrode 160a can be an anode and can include a transparent conductive oxide (TCO) layer, which is formed of a conductive material, e.g., a transparent conductive oxide material, having a relatively high work function, and a reflective layer.

For example, the transparent conductive oxide material can include at least one of indium-tin-oxide (ITO), indium-zinc-oxide (IZO), indium-tin-zinc oxide (ITZO), tin oxide (SnO), zinc oxide (ZnO), indium-copper-oxide (ICO) and aluminum-zinc-oxide (Al:ZnO, AZO), and the reflective layer can include at least one of silver (Ag), an alloy of Ag and one of palladium (Pd), Cu, In and Nd and aluminum-palladium-copper alloy (APC). For example, the first electrode 160a can have a double-layered structure of Ag/ITO or APC/ITO or a triple-layered structure of ITO/Ag/ITO or ITO/APC/ITO.

A pixel definition layer 156 is formed on the third planarization layer 150c at a boundary of the pixel region. The pixel definition layer 156 covers an edge of the first electrode 160a and has an opening to expose a center of the first electrode 160a. Namely, the opening of the pixel definition layer 156 corresponds to the OLED D.

The pixel definition layer 156 can have a light-absorbing property. The pixel definition layer 156 can be a black pixel definition layer or a gray pixel definition layer. The pixel definition layer 156 can include a black particle, e.g., a light-absorbing particle, disposed in an organic material, e.g., a binder. For example, the organic material can be at least one of photo-acryl, benzocyclobutene and polyimide, and the black particle can be at least one of carbon black, carbon nano tube (CNT) and graphene.

The pixel definition layer 156 can have a first optical density (OD) of 1.0 or less. For example, the first OD can be in a range of 0.5 to 1.0.

In the organic light emitting display device, after the first electrode 160a is formed, the pixel definition layer 156 covering an edge of the first electrode 160a is formed by coating the organic material including the black particle and performing a mask process. When the pixel definition layer having a relatively high OD, an amount of the black particle in the organic material is increased, and an amount of the organic material is decreased. As a result, a curing process to the organic material is incompletely performed so that a particle can remain on the first electrode 160a. In this case, there can be a problem in a driving voltage and a lifespan of the OLED D.

In the organic light emitting display device 100 of the present disclosure, the above problem can be prevented by decreasing an amount in the pixel definition layer 156 so that the pixel definition layer 156 has a relatively low OD.

When the pixel definition layer 156 has a relatively low OD, an external light (e.g., an ambient light) can pass through the pixel definition layer 156 and be reflected by an electrode and/or a signal line under the pixel definition layer 156 so that the external light reflection can be increased. In addition, the external light passing through the pixel definition layer 156 can be incident to the first semiconductor layer 110 of the first TFT T1 and/or the second semiconductor layer 136 of the second TFT T2 so that the current leakage can occur. For example, when the external light is incident to the first semiconductor layer 110 of the first TFT T1, which is formed of an oxide semiconductor material having a high mobility, the performance of the first TFT T1 can be significantly degraded by the current leakage.

However, in the organic light emitting display device 100 of the present disclosure, the second and third planarization layers 150b and 150c under the pixel definition layer 156 respectively include the first and second scattering particles 152 and 154, the above problems of the external light reflection and/or the current leakage from the first and second TFTs T1 and T2 can be prevented or minimized.

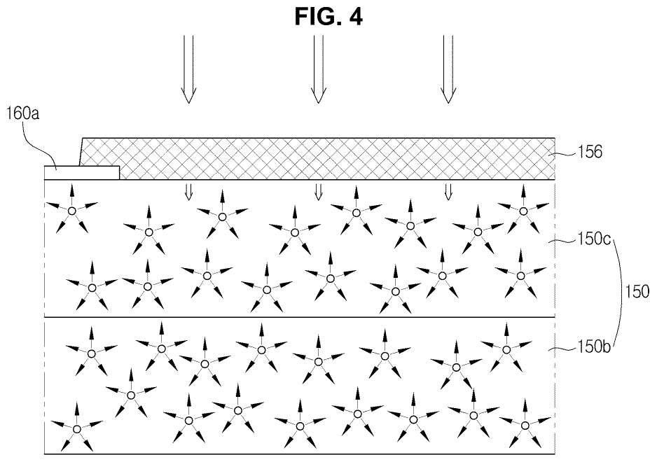

Namely, referring to FIG. 4, which is a schematic cross-sectional view illustrating the extinction of light within a planarization layer, a part of the external light passes through the pixel definition layer 156 having a relatively low OD and is incident to the planarization layer 150. In the organic light emitting display device 100 of the present disclosure, since the second and third planarization layers 150b and 150c respectively include the first and second scattering particles 152 and 154, the external light passing through the pixel definition layer 156 is scattered by the first and second scattering particles 152 and 154 in the second and third planarization layers 150b and 150c and is extinguished by the destructive interference. Accordingly, the display quality degradation by the external light reflection and/or the current leakage of the TFTs T1 and T2 can be prevented or minimized.

Referring again to FIG. 3, a first spacer 158a having a reverse-tapered shape and a second spacer 158b having a tapered shape are disposed on the pixel definition layer 156. For example, each of the first spacer 158a and the second spacer 158b can be formed of an organic insulating material, e.g., photo-acryl or benzocyclobutene (BCB) and can have a single-layered structure or a multi-layered structure. At least one of the first spacer 158a and the second spacer 158b can be omitted.

An organic light emitting layer 160b covering the first electrode 160a, the pixel definition layer 156 and the first and second spacers 158a and 158b is disposed. The organic light emitting layer 160b contacts the first electrode 160a in the opening of the pixel definition layer 156. Namely, the organic light emitting layer 160b can be formed to contact an upper surface of the first electrode 160a, a side surface and an upper surface of the pixel definition layer 156, an upper surface of the first spacer 158a and a side surface and an upper surface of the second spacer 158b.

For example, the organic light emitting layer 160b can include an organic emitting material layer (EML) including a host and a dopant. In addition, the organic light emitting layer 160b can further include at least one of a hole injection layer (HIL), a hole transporting layer (HTL), an electron blocking layer (EBL), a hole blocking layer (HBL), an electron transporting layer (ETL) and an electron injection layer (EIL) to have a multi-layered structure.

A second electrode 160c is formed over the substrate 102 where the organic light emitting layer 160b is formed. The second electrode 160c covers an entire surface of the display area. The second electrode 160c can be formed of at least one of ITO, IZO, Al, Ag, Cu, Pb, magnesium (Mg), Mo, Ti and their alloy and have a single-layered structure or a multi-layered structure. The second electrode 160c can have a thin profile (small thickness) to provide a light transmittance property (or a semi-transmittance property).

The first electrode 160a, the organic light emitting layer 160b and the second electrode 160c constitute an organic light emitting diode D. The organic light emitting diode D can emit the red, green and blue light in the red, green and blue pixel region, respectively. Alternatively, the organic light emitting diode D can emit the with light in the red, green, blue and white pixel regions.

In the organic light emitting display device 100, the light from the light emitting layer 160b passes through the second electrode 160c and a color filter layer 182 to display an image. Namely, the organic light emitting display device 100 of the present disclosure is a top-emission type display device.

An encapsulation layer (or encapsulation film) 162 is formed on the second electrode 160c to prevent penetration of moisture into the organic light emitting diode D. The encapsulation layer 162 can cover an entire substrate 102. The encapsulation layer 162 includes a first inorganic insulating layer 162a, an organic insulating layer 162b and a second inorganic insulating layer 162c sequentially stacked.

Each of the first and second inorganic insulating layers 162a and 162c can be formed of an inorganic insulating material, e.g., silicon oxide or silicon nitride. The organic insulating layer 162b can be formed of an organic insulating material, e.g., acryl resin, epoxy resin, phenolic resin, polyamide resin or polyimide resin.

A second buffer layer 164 is disposed on the encapsulation layer 162 and over an entire surface of the substrate 102. The moisture and/or oxygen can be blocked by the second buffer layer 164. For example, the second buffer layer 164 can be formed of an inorganic insulating material, e.g., silicon oxide or silicon nitride, and have a single-layered structure or a multi-layered structure.

A plurality of bridge patterns 166 are disposed on the second buffer layer 164. For example, each of the plurality of bridge patterns 166 can be formed of one of ITO, IZO, Al, Ag, Cu, Pb, Mg, Mo, Ti and their alloys and can have a single-layered structure or a multi-layered structure.

A fourth interlayer insulating layer 168 is disposed on the bridge pattern 166 and over an entire surface of the substrate 102. The fourth interlayer insulating layer 168 can be formed of an inorganic insulating material, e.g., silicon oxide or silicon nitride, or an organic insulating material, e.g., photo-acryl or BCB, and have a single-layered structure or a multi-layered structure.

A sensor pattern 170 is disposed on the fourth interlayer insulating layer 168. The sensor pattern 170 can include a plurality of first sensor patterns 170a, which are spaced apart from each other, and a plurality of second sensor patterns 170b, which are disposed between adjacent first sensor patterns 170a. The first sensor pattern 170a is connected to the bridge pattern 166 through a contact hole in the fourth interlayer insulating layer 168.

For example, each of the first and second sensor patterns 170a and 170b can be formed of one of ITO, IZO, Al, Ag, Cu, Pb, Mg, Mo, Ti and their alloys and can have a single-layered structure or a multi-layered structure.

A first protection layer 172 is disposed over an entire surface of the substrate 102 to cover the first and second sensor patterns 170a and 170b. The first protection layer 172 can be formed of an inorganic insulating material, e.g., silicon oxide or silico nitride, or an organic insulating material, e.g., photo-acryl or benzocyclobutene, and can have a single-layered structure or a multi-layered structure.

A third buffer layer 174 is disposed on the first protection layer 172 and over an entire surface of the substrate 102. The third buffer layer 174 can be formed of an inorganic insulating material, e.g., silicon oxide or silico nitride, and can have a single-layered structure or a multi-layered structure.

A black matrix 180 is disposed on the third buffer layer 174. The black matrix 180 is positioned at a boundary of the pixel region P and include an opening in correspond to the organic light emitting diode D. The opening of the black matrix 180 corresponds to the opening of the pixel definition layer 156.

The black matrix 180 has a second OD being greater than the first OD of the pixel definition layer 156. The second OD of the black matrix 180 can be in a range of 0.8 or more. For example, the second OD can be in a range of 0.8 to 1.8.

The black matrix 180 can include a black particle, e.g., carbon black, CNT or graphene.

In an embodiment of the present disclosure, each of the pixel definition layer 156 and the black matrix 180 can be formed by stacking at least two of a red color filter layer, a green color filter layer and a blue color filter layer.

A size (e.g., a planar area) of the opening in the black matrix 180 can be greater than that of the opening in the pixel definition layer 156. When an opening of the black matrix 180 can be equal to or smaller than an opening of the pixel definition layer 156, a viewing angle of the organic light emitting display device 100 can be decreased.

The black matrix 180 has the opening larger than the opening of the pixel definition layer 156, and the pixel definition layer 156 has a relatively low OD. Accordingly, the external light can pass through the opening of the black matrix 180 and an edge of the pixel definition layer 156 so that there can be a problem of the external light reflection and/or the current leakage from the TFT.

However, as described above, in the organic light emitting display device 100 of the present disclosure, since the planarization layer 150, e.g., the second and third planarization layers 150b and 150c, under the pixel definition layer 156 includes the first and second scattering particles 152 and 154, the problem of the external light reflection and the current leakage in the TFTs T1 and T2 caused by the black matrix 180, which includes an opening larger than an opening of the pixel definition layer 156 and the pixel definition layer 156, which has a relatively low OD, can be prevented or minimized.

A color filter layer 182 corresponding to the black matrix 180 is disposed on the third buffer layer 174. The color filter layer 182 can include a red color filter corresponding to the red pixel region, a green color filter corresponding to the green pixel region and a blue color filter corresponding to the blue pixel region.

Since the organic light emitting display device 100 includes the color filter layer 182, the external light reflection can be reduced or minimized. Namely, since the organic light emitting display device 100 includes the color filter layer 182 without a polarization plate, the external light reflection can be reduced with minimizing the luminance decrease.

A second protection layer 184 is disposed on the black matrix 180 and the color filter layer 182 and over an entire surface of the substrate 102. The second protection layer 184 can be formed of an inorganic insulating material, e.g., silicon oxide or silico nitride or an organic insulating material, e.g., photo-acryl or benzocyclobutene, and can have a single-layered structure or a multi-layered structure.

In the organic light emitting display device 100 of the present disclosure, the pixel definition layer 156 has a relatively low OD, e.g., a relatively small amount of the black particle, so that a problem resulting from a particle in a fabricating process can be prevented.

In addition, since the planarization layer 150, e.g., the second and third planarization layers 150b and 150c, under the pixel definition layer 156 includes the first and second scattering particles 152 and 154, the problem of the external light reflection and the current leakage in the TFTs T1 and T2 can be reduced, prevented or minimized.

Moreover, since the organic light emitting display device 100 includes the color filter layer 182 without a polarization plate, the external light reflection can be reduced with minimizing the luminance decrease.

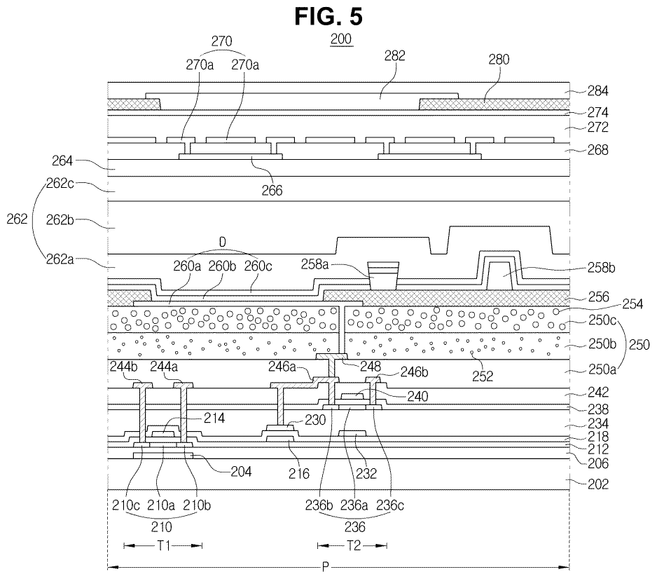

FIG. 5 is a schematic cross-sectional view illustrating an organic light emitting display device according to a second embodiment of the present disclosure.

As shown in FIG. 5, the organic light emitting display device 200 includes a substrate 202, a TFT on the substrate 202, a planarization layer 250 covering the TFT, an OLED D on the planarization layer 250 and a pixel definition layer 256 on the planarization layer 250 and at a boundary of a pixel region P.

A plurality of pixel regions P are defined on the substrate 202. The substrate 202 can be a glass substrate or a plastic substrate. In an embodiment of the present disclosure, the substrate 202 can have a triple-layered structure including a first polyimide (PI) layer, a second PI layer and an interlayer inorganic layer between the first and second PI layers.

A first light shielding pattern 204 is disposed on the substrate 202, and a first buffer layer 206 covering the first light shielding pattern 204 is disposed over the substrate 202.

A first semiconductor layer 210 corresponding to the first light shielding pattern 204 is disposed on the first buffer layer 206. The first semiconductor layer 210 can include one of a poly-semiconductor material, an amorphous semiconductor material and an oxide semiconductor material. When the first light shielding pattern 204 and the first buffer layer 206 are omitted, the first semiconductor layer 210 can be directly disposed on the substrate 202.

In an example embodiment of the present disclosure, the first semiconductor layer 210 can be formed of a poly-semiconductor material, e.g., polycrystalline silicon. The first semiconductor layer 210 can include a first channel region 210a, a first source region 210b at one side of the first channel region 210a and a first drain region 210c at the other side of the first channel region 210a. Impurities can be dopped into the first source and drain regions 210b and 210c.

A first gate insulating layer 212 covering the first semiconductor layer 210 is disposed over the first buffer layer 206.

A first gate electrode 214 corresponding to the first channel region 210a of the first semiconductor layer 210 is disposed on the first gate insulating layer 212. In addition, a first capacitor electrode 216, which is spaced apart from the first gate electrode 214, is disposed on the first gate insulating layer 212.

A first interlayer insulating layer 218 covering the first gate electrode 214 and the first capacitor electrode 216 is disposed on the first gate insulating layer 212.

A second capacitor electrode 230 corresponding to the first capacitor electrode 216 and a second light shielding pattern 232 spaced apart from the second capacitor electrode 230 are disposed on the first interlayer insulating layer 218.

A second interlayer insulating layer 234 covering the first second capacitor electrode 230 and the second light shielding pattern 232 is disposed on the first interlayer insulating layer 218.

A second semiconductor layer 236 corresponding to the second light shielding pattern 232 is disposed on the second interlayer insulating layer 234. The second semiconductor layer 236 can include one of a poly-semiconductor material, an amorphous semiconductor material and an oxide semiconductor material.

In an example embodiment of the present disclosure, the second semiconductor layer 236 can be formed of an oxide semiconductor material, e.g., indium-gallium-zinc oxide (IGZO), zinc oxide (ZnO), tin oxide (SnO2), copper oxide (Cu2O), nickel oxide (NiO), indium-tin-zinc oxide (ITZO) or indium-aluminum-zinc oxide (IAZO). The second semiconductor layer 236 can include a second channel region 236a, a second source region 236b at one side of the second channel region 236a and a second drain region 236c at the other side of the second channel region 236a. Impurities can be dopped into the second source and drain regions 236b and 236c.

A second gate insulating layer 238 covering the second semiconductor layer 236 is disposed over the second interlayer insulating layer 234.

A second gate electrode 240 corresponding to the second channel region 236a of the second semiconductor layer 236 is disposed on the second gate insulating layer 238.

A third interlayer insulating layer 242 covering the second gate electrode 240 is disposed on the second gate insulating layer 238.

A first source electrode 244a, a first drain electrode 244b, a second source electrode 246a and a second drain electrode 246b are disposed on the third interlayer insulating layer 242.

The first source electrode 244a and the first drain electrode 244b are respectively connected to the first source region 210b and the first drain region 210c via contact holes through the third interlayer insulating layer 242, the second gate insulating layer 238, the second interlayer insulating layer 234, the first interlayer insulating layer 218 and the first gate insulating layer 212. The first source electrode 244a is connected to the first capacitor electrode 216 via a contact hole through the third interlayer insulating layer 242, the second gate insulating layer 238, the second interlayer insulating layer 234 and the first interlayer insulating layer 218.

The second source electrode 246a and the second drain electrode 246b are respectively connected to the second source region 236b and the second drain region 236c via contact holes through the third interlayer insulating layer 242 and the second gate insulating layer 238. The second source electrode 246a is connected to the second capacitor electrode 230 via a contact hole through the third interlayer insulating layer 242, the second gate insulating layer 238 and the second interlayer insulating layer 234.

The first semiconductor layer 210, the first gate electrode 214, the first source electrode 244a and the first drain electrode 244b constitute a first TFT T1, and the second semiconductor layer 236, the second gate electrode 240, the second source electrode 246a and the second drain electrode 246b constitute a second TFT T2. For example, the first TFT T1 can be a switching TFT, and the second TFT can be a driving TFT.

The organic light emitting display device of the present disclosure includes the first and second TFTs T1 and T2. Each of the first semiconductor layer 210 of the first TFT T1 and the second semiconductor layer 236 of the second TFT T2 can include one of a poly-semiconductor material, an amorphous semiconductor material and an oxide semiconductor material, and at least one of the first semiconductor layer 210 of the first TFT T1 and the second semiconductor layer 236 of the second TFT T2 can include the oxide semiconductor material. In an example embodiment of the present disclosure, the first semiconductor layer 210 of the first TFT T1 can be formed of the poly-semiconductor material, e.g., polycrystalline silicon, and the second semiconductor layer 236 of the second TFT T2 can be formed of the oxide semiconductor material.

A planarization layer 250 covering the first source and drain electrodes 244a and 244b and the second source and drain electrodes 246a and 246b is disposed on the third interlayer insulating layer 242. The planarization layer 250 can be formed of an organic insulating material, e.g., photo-aryl or BCB.

The planarization layer 250 can include a first planarization layer 250a on the first source and drain electrodes 244a and 244b and the second source and drain electrodes 246a and 246b, a second planarization layer 250b on the first planarization layer 250a and a third planarization layer 250c on the second planarization layer 250b.

A connection electrode 248 corresponding to the second source electrode 246a is disposed on the first planarization layer 250a. The connection electrode 248 can connected to the second source electrode 246a through a contact hole in the first planarization layer 250a.

The second planarization layer 250b is disposed on the first planarization layer 250a to cover the connection electrode 248, and the third planarization layer 250c is disposed on the second planarization layer 250b. A flatness of an anode 260a of the OLED D can be degraded by a step difference resulting from an electrode or a signal line under the anode 260a so that there can be a problem, e.g., a lifespan decrease of the OLED D. However, in the organic light emitting display device 200 of the present disclosure, the step difference can be compensated by the third planarization layer 250c so that the above problem can be prevented.

In FIG. 5, the planarization layer 250 includes the first to third planarization layers 250a, 250b and 250c to have a triple-layered structure. In an embodiment of the present disclosure, the connection electrode 248 and the first planarization layer 250a can be omitted so that the planarization layer 250 can have a double-layered structure. In an embodiment of the present disclosure, additional planarization layer can be further disposed so that the planarization layer 250 can have four or more layers.

The planarization layer 250 includes a scattering particle. For example, in the planarization layer 250, the scattering particle can be dispersed in an organic insulating material.

In an embodiment of the present disclosure, at least one of the first to third planarization layers 250a, 250b and 250c can include the scattering particle. For example, the second planarization layer 250b can include a first scattering particle 252, and the third planarization layer 250c can include a second scattering particle 254.

Each of the first and second scattering particles 252 and 254 can be formed of an inorganic material, e.g., silicon oxide (SiO2), or an organic material, e.g., polyoxyethylene, polyoxyethylene glycol, polyoxypropylene alkyl ether, polyoxypropylene monoalkyl ether, polyoxypropylene alkyl, polyoxyethylene tallowamine, polyoxyethylene oleylamine, polyoxyethylene sterylamine, polyoxyethylene laurylamine, polyoxyethylene sorbitan ester, polyoxyethylene octyl ether, polyoxyethylene glycerin ether, polyacrylic acid, polysulfonic acid, polyacrylic amine, triethylene amine, their copolymer or their blocked-copolymer.

The first scattering particle 252 has a first diameter (e.g., a size), and the second scattering particle 254 has a second diameter being greater than the first diameter. The first scattering particle 252 can have a diameter in a range of 1 nm to 80 nm, and the second scattering particle 254 can have a diameter in a range of 100 nm to 1000 nm. For example, the first scattering particle 252 can have a diameter in a range of 10 nm to 80 nm, and the second scattering particle 254 can have a diameter in a range of 300 nm to 700 nm. A Rayleigh scattering can occur by the first scattering particle 252, and a Mie scattering can occur by the second scattering particle 254.

In FIG. 5, the first planarization layer 250a is formed by an organic insulating material without a scattering particle. Alternatively, the first planarization layer 250a can include a third scattering particle. The third scattering particle can have a diameter being same or substantially same as the second scattering particle 254. For example, the third scattering particle can have a diameter in a range of 100 nm to 1000 nm, e.g., 300 nm to 700 nm. As a result, the Mie scattering can occur by the third scattering particle.

A first electrode 260a is disposed on the second planarization layer 250b. The first electrode 260a corresponds to the connection electrode 248 and is connected to the connection electrode 248 through a contact hole in the second and third planarization layers 250b and 250c.

For example, the first electrode 260a is separately formed in each pixel region P. The first electrode 260a can be an anode and can include a transparent conductive oxide (TCO) layer, which is formed of a conductive material, e.g., a transparent conductive oxide material, having a relatively high work function, and a reflective layer.

For example, the transparent conductive oxide material can include at least one of indium-tin-oxide (ITO), indium-zinc-oxide (IZO), indium-tin-zinc oxide (ITZO), tin oxide (SnO), zinc oxide (ZnO), indium-copper-oxide (ICO) and aluminum-zinc-oxide (Al:ZnO, AZO), and the reflective layer can include at least one of silver (Ag), an alloy of Ag and one of palladium (Pd), Cu, In and Nd and aluminum-palladium-copper alloy (APC). For example, the first electrode 260a can have a double-layered structure of Ag/ITO or APC/ITO or a triple-layered structure of ITO/Ag/ITO or ITO/APC/ITO.

A pixel definition layer 256 is formed on the third planarization layer 250c at a boundary of the pixel region. The pixel definition layer 256 covers an edge of the first electrode 260a and has an opening to expose a center of the first electrode 260a.

The pixel definition layer 256 can have a light-absorbing property. The pixel definition layer 256 can be a black pixel definition layer or a gray pixel definition layer. The pixel definition layer 256 can include a black particle, e.g., a light-absorbing particle, disposed in an organic material, e.g., a binder. For example, the organic material can be at least one of photo-acryl, benzocyclobutene and polyimide, and the black particle can be at least one of carbon black, carbon nano tube (CNT) and graphene.

The pixel definition layer 256 can have a first optical density (OD) of 1.0 or less. For example, the first OD can be in a range of 0.5 to 1.0.

In the organic light emitting display device, after the first electrode 260a is formed, the pixel definition layer 256 covering an edge of the first electrode 260a is formed by coating the organic material including the black particle and performing a mask process. When the pixel definition layer having a relatively high OD, an amount of the black particle in the organic material is increased, and an amount of the organic material is decreased. As a result, a curing process to the organic material is incompletely performed so that a particle can remain on the first electrode 260a. In this case, there can be a problem in a driving voltage and a lifespan of the OLED D.

In the organic light emitting display device 200 of the present disclosure, the above problem can be prevented by decreasing an amount in the pixel definition layer 256 so that the pixel definition layer 256 has a relatively low OD.

When the pixel definition layer 256 has a relatively low OD, an external light (e.g., an ambient light) can pass through the pixel definition layer 256 and be reflected by an electrode and/or a signal line under the pixel definition layer 256 so that the external light reflection can be increased. In addition, the external light passing through the pixel definition layer 256 can be incident to the first semiconductor layer 210 of the first TFT T1 and/or the second semiconductor layer 236 of the second TFT T2 so that the current leakage can occur. For example, when the external light is incident to the first semiconductor layer 210 of the first TFT T1, which is formed of an oxide semiconductor material having a high mobility, the performance of the first TFT T1 can be significantly degraded by the current leakage.

However, in the organic light emitting display device 200 of the present disclosure, the second and third planarization layers 250b and 250c under the pixel definition layer 256 respectively include the first and second scattering particles 252 and 254, the above problems of the external light reflection and/or the current leakage from the first and second TFTs T1 and T2 can be reduced, prevented or minimized.

In addition, the Mie scattering can occur by the second scattering particle 254, and the Rayleigh scattering can occur by the first scattering particle 252. As a result, an amount of the light, which passes through the pixel definition layer 256 and is directed to the first and second TFTs T1 and T2 can be reduced or minimized so that the current leakage in the first and second TFTs T1 and T2 by the external light can be reduced or minimized or prevented.

A first spacer 258a having a reverse-tapered shape and a second spacer 258b having a tapered shape are disposed on the pixel definition layer 256.

An organic light emitting layer 260b covering the first electrode 260a, the pixel definition layer 256 and the first and second spacers 258a and 258b is disposed. The organic light emitting layer 260b contacts the first electrode 260a in the opening of the pixel definition layer 256. Namely, the organic light emitting layer 260b can be formed to contact an upper surface of the first electrode 260a, a side surface and an upper surface of the pixel definition layer 256, an upper surface of the first spacer 258a and a side surface and an upper surface of the second spacer 258b.

For example, the organic light emitting layer 260b can include an organic emitting material layer (EML) including a host and a dopant. In addition, the organic light emitting layer 260b can further include at least one of an HIL, an HTL, an EBL, an HBL, an ETL and an EIL to have a multi-layered structure.

A second electrode 260c is formed over the substrate 202 where the organic light emitting layer 260b is formed. The second electrode 260c covers an entire surface of the display area. The second electrode 260c can be formed of at least one of ITO, IZO, Al, Ag, Cu, Pb, magnesium (Mg), Mo, Ti and their alloy and have a single-layered structure or a multi-layered structure. The second electrode 260c can have a thin profile (small thickness) to provide a light transmittance property (or a semi-transmittance property).

The first electrode 260a, the organic light emitting layer 260b and the second electrode 260c constitute an organic light emitting diode D. The organic light emitting diode D can emit the red, green and blue light in the red, green and blue pixel region, respectively. Alternatively, the organic light emitting diode D can emit the with light in the red, green, blue and white pixel regions.

In the organic light emitting display device 200, the light from the light emitting layer 260b passes through the second electrode 260c and a color filter layer 282 to display an image. Namely, the organic light emitting display device 200 of the present disclosure is a top-emission type display device.

An encapsulation layer (or encapsulation film) 262 is formed on the second electrode 260c to prevent penetration of moisture into the organic light emitting diode D. The encapsulation layer 262 can cover an entire substrate 202. The encapsulation layer 262 includes a first inorganic insulating layer 262a, an organic insulating layer 262b and a second inorganic insulating layer 262c sequentially stacked.

A second buffer layer 264 is disposed on the encapsulation layer 262 and over an entire surface of the substrate 202. The moisture and/or oxygen can be blocked by the second buffer layer 264.

A plurality of bridge patterns 266 are disposed on the second buffer layer 264, and a fourth interlayer insulating layer 268 is disposed on the bridge pattern 266 and over an entire surface of the substrate 202.

A sensor pattern 270 is disposed on the fourth interlayer insulating layer 268. The sensor pattern 270 can include a plurality of first sensor patterns 270a, which are spaced apart from each other, and a plurality of second sensor patterns 270b, which are disposed between adjacent first sensor patterns 270a. The first sensor pattern 270a is connected to the bridge pattern 266 through a contact hole in the fourth interlayer insulating layer 268.

A first protection layer 272 is disposed over an entire surface of the substrate 202 to cover the first and second sensor patterns 270a and 270b, and a third buffer layer 274 is disposed on the first protection layer 272 and over an entire surface of the substrate 202.

A black matrix 280 is disposed on the third buffer layer 274. The black matrix 280 is positioned at a boundary of the pixel region P and include an opening in correspond to the organic light emitting diode D. The opening of the black matrix 280 corresponds to the opening of the pixel definition layer 256.

The black matrix 280 has a second OD being greater than the first OD of the pixel definition layer 256. The second OD of the black matrix 280 can be in a range of 0.8 or more. For example, the second OD can be in a range of 0.8 to 1.8.

A size (e.g., a planar area) of the opening in the black matrix 280 can be greater than that of the opening in the pixel definition layer 256. When an opening of the black matrix 280 can be equal to or smaller than an opening of the pixel definition layer 256, a viewing angle of the organic light emitting display device 200 can be decreased.

The black matrix 280 has the opening larger than the opening of the pixel definition layer 256, and the pixel definition layer 256 has a relatively low OD. Accordingly, the external light can pass through the opening of the black matrix 280 and an edge of the pixel definition layer 256 so that there can be a problem of the external light reflection and/or the current leakage from the TFT.

However, as described above, in the organic light emitting display device 200 of the present disclosure, since the planarization layer 250 under the pixel definition layer 256 includes the first and second scattering particles 252 and 254, the problem of the external light reflection and the current leakage in the TFTs T1 and T2 caused by the black matrix 280, which includes an opening larger than an opening of the pixel definition layer 256 and the pixel definition layer 256, which has a relatively low OD, can be reduced, prevented or minimized.

In addition, the second planarization layer 250b includes the first scattering particle 252 having the first diameter, and the third planarization layer 250c, which is positioned between the second planarization layer 250b and the pixel definition layer 256, includes the second scattering particle 254 having the second diameter, which is larger than the first diameter. Accordingly, the external light toward the TFTs T1 and T2 can be further decreased so that the current leakage in the TFTs T1 and T2 can be further prevented.

A color filter layer 282 corresponding to the black matrix 280 is disposed on the third buffer layer 274. The color filter layer 282 can include a red color filter corresponding to the red pixel region, a green color filter corresponding to the green pixel region and a blue color filter corresponding to the blue pixel region.

Since the organic light emitting display device 200 includes the color filter layer 282, the external light reflection can be reduced or minimized. Namely, since the organic light emitting display device 200 includes the color filter layer 282 without a polarization plate, the external light reflection can be reduced with minimizing the luminance decrease.

A second protection layer 284 is disposed on the black matrix 280 and the color filter layer 282 and over an entire surface of the substrate 202.

In the organic light emitting display device 200 of the present disclosure, the pixel definition layer 256 has a relatively low OD, e.g., a relatively small amount of the black particle, so that a problem resulting from a particle in a fabricating process can be prevented.

In addition, since the planarization layer 250, e.g., the second and third planarization layers 250b and 250c, under the pixel definition layer 256 includes the first and second scattering particles 252 and 254, the problem of the external light reflection and the current leakage in the TFTs T1 and T2 can be reduced, prevented or minimized.

Moreover, since the organic light emitting display device 200 includes the color filter layer 282 without a polarization plate, the external light reflection can be reduced with minimizing the luminance decrease.

Furthermore, the second planarization layer 250b includes the first scattering particle 252 having the first diameter, and the third planarization layer 250c, which is positioned between the second planarization layer 250b and the pixel definition layer 256, includes the second scattering particle 254 having the second diameter, which is larger than the first diameter. Accordingly, the external light toward the TFTs T1 and T2 can be further decreased so that the current leakage in the TFTs T1 and T2 can be further prevented.

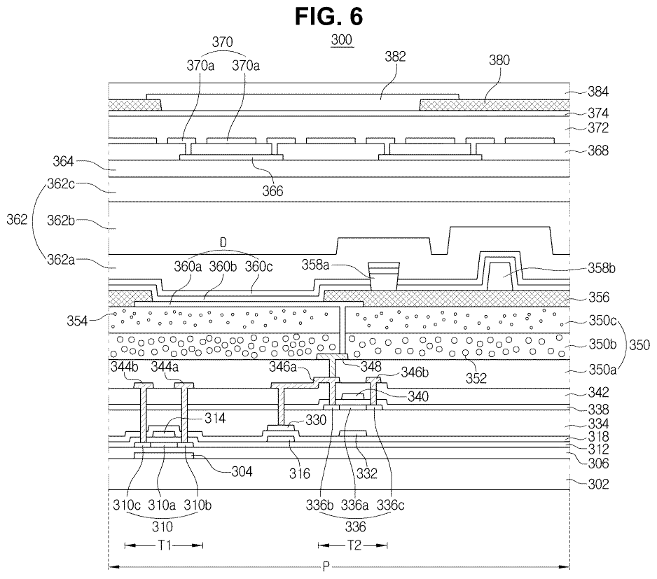

FIG. 6 is a schematic cross-sectional view illustrating an organic light emitting display device according to a third embodiment of the present disclosure.

As shown in FIG. 6, the organic light emitting display device 300 includes a substrate 302, a TFT on the substrate 302, a planarization layer 350 covering the TFT, an OLED D on the planarization layer 350 and a pixel definition layer 356 on the planarization layer 350 and at a boundary of a pixel region P.

A plurality of pixel regions P are defined on the substrate 302. The substrate 302 can be a glass substrate or a plastic substrate. In an embodiment of the present disclosure, the substrate 302 can have a triple-layered structure including a first polyimide (PI) layer, a second PI layer and an interlayer inorganic layer between the first and second PI layers.

A first light shielding pattern 304 is disposed on the substrate 302, and a first buffer layer 306 covering the first light shielding pattern 304 is disposed over the substrate 302.

A first semiconductor layer 310 corresponding to the first light shielding pattern 304 is disposed on the first buffer layer 306. The first semiconductor layer 310 can include one of a poly-semiconductor material, an amorphous semiconductor material and an oxide semiconductor material. When the first light shielding pattern 304 and the first buffer layer 306 are omitted, the first semiconductor layer 310 can be directly disposed on the substrate 302.

In an example embodiment of the present disclosure, the first semiconductor layer 310 can be formed of a poly-semiconductor material, e.g., polycrystalline silicon. The first semiconductor layer 310 can include a first channel region 310a, a first source region 310b at one side of the first channel region 310a and a first drain region 310c at the other side of the first channel region 310a. Impurities can be dopped into the first source and drain regions 310b and 310c.

A first gate insulating layer 312 covering the first semiconductor layer 310 is disposed over the first buffer layer 306.

A first gate electrode 314 corresponding to the first channel region 310a of the first semiconductor layer 310 is disposed on the first gate insulating layer 312. In addition, a first capacitor electrode 316, which is spaced apart from the first gate electrode 314, is disposed on the first gate insulating layer 312.

A first interlayer insulating layer 318 covering the first gate electrode 314 and the first capacitor electrode 316 is disposed on the first gate insulating layer 312.

A second capacitor electrode 330 corresponding to the first capacitor electrode 316 and a second light shielding pattern 332 spaced apart from the second capacitor electrode 330 are disposed on the first interlayer insulating layer 318.

A second interlayer insulating layer 334 covering the first second capacitor electrode 330 and the second light shielding pattern 332 is disposed on the first interlayer insulating layer 318.

A second semiconductor layer 336 corresponding to the second light shielding pattern 332 is disposed on the second interlayer insulating layer 334. The second semiconductor layer 336 can include one of a poly-semiconductor material, an amorphous semiconductor material and an oxide semiconductor material.

In an example embodiment of the present disclosure, the second semiconductor layer 336 can be formed of an oxide semiconductor material, e.g., indium-gallium-zinc oxide (IGZO), zinc oxide (ZnO), tin oxide (SnO2), copper oxide (Cu2O), nickel oxide (NiO), indium-tin-zinc oxide (ITZO) or indium-aluminum-zinc oxide (IAZO). The second semiconductor layer 336 can include a second channel region 336a, a second source region 336b at one side of the second channel region 336a and a second drain region 336c at the other side of the second channel region 336a. Impurities can be dopped into the second source and drain regions 336b and 336c.

A second gate insulating layer 338 covering the second semiconductor layer 336 is disposed over the second interlayer insulating layer 334.

A second gate electrode 340 corresponding to the second channel region 336a of the second semiconductor layer 336 is disposed on the second gate insulating layer 338.

A third interlayer insulating layer 342 covering the second gate electrode 340 is disposed on the second gate insulating layer 338.

A first source electrode 344a, a first drain electrode 344b, a second source electrode 346a and a second drain electrode 346b are disposed on the third interlayer insulating layer 342.

The first source electrode 344a and the first drain electrode 344b are respectively connected to the first source region 310b and the first drain region 310c via contact holes through the third interlayer insulating layer 342, the second gate insulating layer 338, the second interlayer insulating layer 334, the first interlayer insulating layer 318 and the first gate insulating layer 312. The first source electrode 344a is connected to the first capacitor electrode 316 via a contact hole through the third interlayer insulating layer 342, the second gate insulating layer 338, the second interlayer insulating layer 334 and the first interlayer insulating layer 318.

The second source electrode 346a and the second drain electrode 346b are respectively connected to the second source region 336b and the second drain region 336c via contact holes through the third interlayer insulating layer 342 and the second gate insulating layer 338. The second source electrode 346a is connected to the second capacitor electrode 330 via a contact hole through the third interlayer insulating layer 342, the second gate insulating layer 338 and the second interlayer insulating layer 334.

The first semiconductor layer 310, the first gate electrode 314, the first source electrode 344a and the first drain electrode 344b constitute a first TFT T1, and the second semiconductor layer 336, the second gate electrode 340, the second source electrode 346a and the second drain electrode 346b constitute a second TFT T2. For example, the first TFT T1 can be a switching TFT, and the second TFT can be a driving TFT.

The organic light emitting display device of the present disclosure includes the first and second TFTs T1 and T2. Each of the first semiconductor layer 310 of the first TFT T1 and the second semiconductor layer 336 of the second TFT T2 can include one of a poly-semiconductor material, an amorphous semiconductor material and an oxide semiconductor material, and at least one of the first semiconductor layer 310 of the first TFT T1 and the second semiconductor layer 336 of the second TFT T2 can include the oxide semiconductor material. In an example embodiment of the present disclosure, the first semiconductor layer 310 of the first TFT T1 can be formed of the poly-semiconductor material, e.g., polycrystalline silicon, and the second semiconductor layer 336 of the second TFT T2 can be formed of the oxide semiconductor material.

A planarization layer 350 covering the first source and drain electrodes 344a and 344b and the second source and drain electrodes 346a and 346b is disposed on the third interlayer insulating layer 342. The planarization layer 350 can be formed of an organic insulating material, e.g., photo-aryl or BCB.

The planarization layer 350 can include a first planarization layer 350a on the first source and drain electrodes 344a and 344b and the second source and drain electrodes 346a and 346b, a second planarization layer 350b on the first planarization layer 350a and a third planarization layer 350c on the second planarization layer 350b.

A connection electrode 348 corresponding to the second source electrode 346a is disposed on the first planarization layer 350a. The connection electrode 348 can connected to the second source electrode 346a through a contact hole in the first planarization layer 350a.

The second planarization layer 350b is disposed on the first planarization layer 350a to cover the connection electrode 348, and the third planarization layer 350c is disposed on the second planarization layer 350b. A flatness of an anode 360a of the OLED D can be degraded by a step difference resulting from an electrode or a signal line under the anode 360a so that there can be a problem, e.g., a lifespan decrease of the OLED D. However, in the organic light emitting display device 300 of the present disclosure, the step difference can be compensated by the third planarization layer 350c so that the above problem can be prevented.

In FIG. 6, the planarization layer 350 includes the first to third planarization layers 350a, 350b and 350c to have a triple-layered structure. In an embodiment of the present disclosure, the connection electrode 348 and the first planarization layer 350a can be omitted so that the planarization layer 350 can have a double-layered structure. In an embodiment of the present disclosure, additional planarization layer can be further disposed so that the planarization layer 350 can have four or more layers.

The planarization layer 350 includes a scattering particle. For example, in the planarization layer 350, the scattering particle can be dispersed in an organic insulating material.

In an embodiment of the present disclosure, at least one of the first to third planarization layers 350a, 350b and 350c can include the scattering particle. For example, the second planarization layer 350b can include a first scattering particle 352, and the third planarization layer 350c can include a second scattering particle 354.

Each of the first and second scattering particles 352 and 354 can be formed of an inorganic material, e.g., silicon oxide (SiO2), or an organic material, e.g., polyoxyethylene, polyoxyethylene glycol, polyoxypropylene alkyl ether, polyoxypropylene monoalkyl ether, polyoxypropylene alkyl, polyoxyethylene tallowamine, polyoxyethylene oleylamine, polyoxyethylene sterylamine, polyoxyethylene laurylamine, polyoxyethylene sorbitan ester, polyoxyethylene octyl ether, polyoxyethylene glycerin ether, polyacrylic acid, polysulfonic acid, polyacrylic amine, triethylene amine, their copolymer or their blocked-copolymer.

The first scattering particle 352 has a first diameter (e.g., a size), and the second scattering particle 354 has a second diameter being smaller than the first diameter. The first scattering particle 352 can have a diameter in a range of 100 nm to 1000 nm, and the second scattering particle 354 can have a diameter in a range of 1 nm to 80 nm. For example, the first scattering particle 352 can have a diameter in a range of 300 nm to 700 nm, and the second scattering particle 354 can have a diameter in a range of 10 nm to 80 nm. A Mie scattering can occur by the first scattering particle 352, and a Rayleigh scattering can occur by the second scattering particle 354.

In FIG. 6, the first planarization layer 350a is formed by an organic insulating material without a scattering particle. Alternatively, the first planarization layer 350a can include a third scattering particle. The third scattering particle can have a diameter being same or substantially same as the second scattering particle 354. For example, the third scattering particle can have a diameter in a range of 1 nm to 80 nm, e.g., 10 nm to 70 nm. As a result, the Rayleigh scattering can occur by the third scattering particle.

A first electrode 360a is disposed on the second planarization layer 350b. The first electrode 360a corresponds to the connection electrode 348 and is connected to the connection electrode 348 through a contact hole in the second and third planarization layers 350b and 350c.

For example, the first electrode 360a is separately formed in each pixel region P. The first electrode 360a can be an anode and can include a transparent conductive oxide (TCO) layer, which is formed of a conductive material, e.g., a transparent conductive oxide material, having a relatively high work function, and a reflective layer.

For example, the transparent conductive oxide material can include at least one of indium-tin-oxide (ITO), indium-zinc-oxide (IZO), indium-tin-zinc oxide (ITZO), tin oxide (SnO), zinc oxide (ZnO), indium-copper-oxide (ICO) and aluminum-zinc-oxide (Al:ZnO, AZO), and the reflective layer can include at least one of silver (Ag), an alloy of Ag and one of palladium (Pd), Cu, In and Nd and aluminum-palladium-copper alloy (APC). For example, the first electrode 360a can have a double-layered structure of Ag/ITO or APC/ITO or a triple-layered structure of ITO/Ag/ITO or ITO/APC/ITO.

A pixel definition layer 356 is formed on the third planarization layer 350c at a boundary of the pixel region. The pixel definition layer 356 covers an edge of the first electrode 360a and has an opening to expose a center of the first electrode 360a.

The pixel definition layer 356 can have a light-absorbing property. The pixel definition layer 356 can be a black pixel definition layer or a gray pixel definition layer. The pixel definition layer 356 can include a black particle, e.g., a light-absorbing particle, disposed in an organic material, e.g., a binder. For example, the organic material can be at least one of photo-acryl, benzocyclobutene and polyimide, and the black particle can be at least one of carbon black, carbon nano tube (CNT) and graphene.

The pixel definition layer 356 can have a first optical density (OD) of 1.0 or less. For example, the first OD can be in a range of 0.5 to 1.0.

In the organic light emitting display device, after the first electrode 360a is formed, the pixel definition layer 356 covering an edge of the first electrode 360a is formed by coating the organic material including the black particle and performing a mask process. When the pixel definition layer having a relatively high OD, an amount of the black particle in the organic material is increased, and an amount of the organic material is decreased. As a result, a curing process to the organic material is incompletely performed so that a particle can remain on the first electrode 360a. In this case, there can be a problem in a driving voltage and a lifespan of the OLED D.

In the organic light emitting display device 300 of the present disclosure, the above problem can be prevented by decreasing an amount in the pixel definition layer 356 so that the pixel definition layer 356 has a relatively low OD.

When the pixel definition layer 356 has a relatively low OD, an external light (e.g., an ambient light) can pass through the pixel definition layer 356 and be reflected by an electrode and/or a signal line under the pixel definition layer 356 so that the external light reflection can be increased. In addition, the external light passing through the pixel definition layer 356 can be incident to the first semiconductor layer 310 of the first TFT T1 and/or the second semiconductor layer 336 of the second TFT T2 so that the current leakage can occur. For example, when the external light is incident to the first semiconductor layer 310 of the first TFT T1, which is formed of an oxide semiconductor material having a high mobility, the performance of the first TFT T1 can be significantly degraded by the current leakage.

However, in the organic light emitting display device 300 of the present disclosure, the second and third planarization layers 350b and 350c under the pixel definition layer 356 respectively include the first and second scattering particles 352 and 354, the above problems of the external light reflection and/or the current leakage from the first and second TFTs T1 and T2 can be reduced, prevented or minimized.

In addition, the Rayleigh scattering can occur by the second scattering particle 354, and the Mie scattering can occur by the first scattering particle 352. As a result, an amount of the light, which passes through the pixel definition layer 356 and is directed to the first and second TFTs T1 and T2 can be reduced or minimized so that the current leakage in the first and second TFTs T1 and T2 by the external light can be reduced, minimized or prevented.

A first spacer 358a having a reverse-tapered shape and a second spacer 358b having a tapered shape are disposed on the pixel definition layer 356.

An organic light emitting layer 360b covering the first electrode 360a, the pixel definition layer 356 and the first and second spacers 358a and 358b is disposed. The organic light emitting layer 360b contacts the first electrode 360a in the opening of the pixel definition layer 356. Namely, the organic light emitting layer 360b can be formed to contact an upper surface of the first electrode 360a, a side surface and an upper surface of the pixel definition layer 356, an upper surface of the first spacer 358a and a side surface and an upper surface of the second spacer 358b.

For example, the organic light emitting layer 360b can include an organic emitting material layer (EML) including a host and a dopant. In addition, the organic light emitting layer 360b can further include at least one of an HIL, an HTL, an EBL, an HBL, an ETL and an EIL to have a multi-layered structure.

A second electrode 360c is formed over the substrate 302 where the organic light emitting layer 360b is formed. The second electrode 360c covers an entire surface of the display area. The second electrode 360c can be formed of at least one of ITO, IZO, Al, Ag, Cu, Pb, magnesium (Mg), Mo, Ti and their alloy and have a single-layered structure or a multi-layered structure. The second electrode 360c can have a thin profile (small thickness) to provide a light transmittance property (or a semi-transmittance property).

The first electrode 360a, the organic light emitting layer 360b and the second electrode 360c constitute an organic light emitting diode D. The organic light emitting diode D can emit the red, green and blue light in the red, green and blue pixel region, respectively. Alternatively, the organic light emitting diode D can emit the with light in the red, green, blue and white pixel regions.

In the organic light emitting display device 300, the light from the light emitting layer 360b passes through the second electrode 360c and a color filter layer 382 to display an image. Namely, the organic light emitting display device 300 of the present disclosure is a top-emission type display device.

An encapsulation layer (or encapsulation film) 362 is formed on the second electrode 360c to prevent penetration of moisture into the organic light emitting diode D. The encapsulation layer 362 can cover an entire substrate 302. The encapsulation layer 362 includes a first inorganic insulating layer 362a, an organic insulating layer 362b and a second inorganic insulating layer 362c sequentially stacked.

A second buffer layer 364 is disposed on the encapsulation layer 362 and over an entire surface of the substrate 302. The moisture and/or oxygen can be blocked by the second buffer layer 364.

A plurality of bridge patterns 366 are disposed on the second buffer layer 364, and a fourth interlayer insulating layer 368 is disposed on the bridge pattern 366 and over an entire surface of the substrate 302.

A sensor pattern 370 is disposed on the fourth interlayer insulating layer 368. The sensor pattern 370 can include a plurality of first sensor patterns 370a, which are spaced apart from each other, and a plurality of second sensor patterns 370b, which are disposed between adjacent first sensor patterns 370a. The first sensor pattern 370a is connected to the bridge pattern 366 through a contact hole in the fourth interlayer insulating layer 368.

A first protection layer 372 is disposed over an entire surface of the substrate 302 to cover the first and second sensor patterns 370a and 370b, and a third buffer layer 374 is disposed on the first protection layer 372 and over an entire surface of the substrate 302.

A black matrix 380 is disposed on the third buffer layer 374. The black matrix 380 is positioned at a boundary of the pixel region P and include an opening in correspond to the organic light emitting diode D. The opening of the black matrix 380 corresponds to the opening of the pixel definition layer 356.

The black matrix 380 has a second OD being greater than the first OD of the pixel definition layer 356. The second OD of the black matrix 380 can be in a range of 0.8 or more. For example, the second OD can be in a range of 0.8 to 1.8.

A size (e.g., a planar area) of the opening in the black matrix 380 can be greater than that of the opening in the pixel definition layer 356. When an opening of the black matrix 380 can be equal to or smaller than an opening of the pixel definition layer 356, a viewing angle of the organic light emitting display device 300 can be decreased.

The black matrix 380 has the opening larger than the opening of the pixel definition layer 356, and the pixel definition layer 356 has a relatively low OD. Accordingly, the external light can pass through the opening of the black matrix 380 and an edge of the pixel definition layer 356 so that there can be a problem of the external light reflection and/or the current leakage from the TFT.

However, as described above, in the organic light emitting display device 300 of the present disclosure, since the planarization layer 350 under the pixel definition layer 356 includes the first and second scattering particles 352 and 354, the problem of the external light reflection and the current leakage in the TFTs T1 and T2 caused by the black matrix 380, which includes an opening larger than an opening of the pixel definition layer 356 and the pixel definition layer 356, which has a relatively low OD, can be reduced, prevented or minimized.

In addition, the second planarization layer 350b includes the first scattering particle 352 having the first diameter, and the third planarization layer 350c, which is positioned between the second planarization layer 350b and the pixel definition layer 356, includes the second scattering particle 354 having the second diameter, which is smaller than the first diameter. Accordingly, the external light toward the TFTs T1 and T2 can be further decreased so that the current leakage in the TFTs T1 and T2 can be further prevented.

A color filter layer 382 corresponding to the black matrix 380 is disposed on the third buffer layer 374. The color filter layer 382 can include a red color filter corresponding to the red pixel region, a green color filter corresponding to the green pixel region and a blue color filter corresponding to the blue pixel region.

Since the organic light emitting display device 300 includes the color filter layer 382, the external light reflection can be reduced or minimized. Namely, since the organic light emitting display device 300 includes the color filter layer 382 without a polarization plate, the external light reflection can be reduced with minimizing the luminance decrease.

A second protection layer 384 is disposed on the black matrix 380 and the color filter layer 382 and over an entire surface of the substrate 302.

In the organic light emitting display device 300 of the present disclosure, the pixel definition layer 356 has a relatively low OD, e.g., a relatively small amount of the black particle, so that a problem resulting from a particle in a fabricating process can be prevented.

In addition, since the planarization layer 350, e.g., the second and third planarization layers 350b and 350c, under the pixel definition layer 356 includes the first and second scattering particles 352 and 354, the problem of the external light reflection and the current leakage in the TFTs T1 and T2 can be reduced, prevented or minimized.

Moreover, since the organic light emitting display device 300 includes the color filter layer 382 without a polarization plate, the external light reflection can be reduced with minimizing the luminance decrease.

Furthermore, the second planarization layer 350b includes the first scattering particle 352 having the first diameter, and the third planarization layer 350c, which is positioned between the second planarization layer 350b and the pixel definition layer 356, includes the second scattering particle 354 having the second diameter, which is smaller than the first diameter. Accordingly, the external light toward the TFTs T1 and T2 can be further decreased so that the current leakage in the TFTs T1 and T2 can be further prevented.

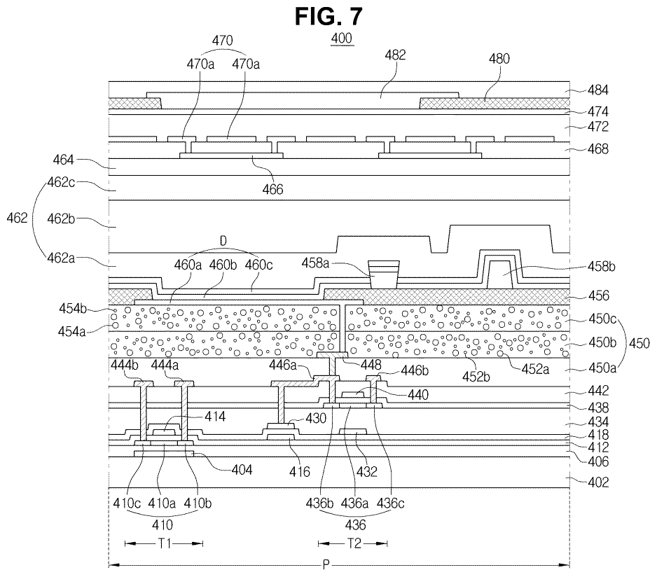

FIG. 7 is a schematic an organic light emitting view illustrating a light emitting display device according to a fourth embodiment of the present disclosure.

As shown in FIG. 7, the organic light emitting display device 400 includes a substrate 402, a TFT on the substrate 402, a planarization layer 450 covering the TFT, an OLED D on the planarization layer 450 and a pixel definition layer 456 on the planarization layer 450 and at a boundary of a pixel region P.

A plurality of pixel regions P are defined on the substrate 402. The substrate 402 can be a glass substrate or a plastic substrate. In an embodiment of the present disclosure, the substrate 302 can have a triple-layered structure including a first polyimide (PI) layer, a second PI layer and an interlayer inorganic layer between the first and second PI layers.

A first light shielding pattern 404 is disposed on the substrate 402, and a first buffer layer 406 covering the first light shielding pattern 404 is disposed over the substrate 402.

A first semiconductor layer 410 corresponding to the first light shielding pattern 404 is disposed on the first buffer layer 406. The first semiconductor layer 410 can include one of a poly-semiconductor material, an amorphous semiconductor material and an oxide semiconductor material. When the first light shielding pattern 404 and the first buffer layer 406 are omitted, the first semiconductor layer 410 can be directly disposed on the substrate 402.

In an example embodiment of the present disclosure, the first semiconductor layer 410 can be formed of a poly-semiconductor material, e.g., polycrystalline silicon. The first semiconductor layer 410 can include a first channel region 410a, a first source region 410b at one side of the first channel region 410a and a first drain region 410c at the other side of the first channel region 410a. Impurities can be dopped into the first source and drain regions 410b and 410c.

A first gate insulating layer 412 covering the first semiconductor layer 410 is disposed over the first buffer layer 406.

A first gate electrode 414 corresponding to the first channel region 410a of the first semiconductor layer 410 is disposed on the first gate insulating layer 412. In addition, a first capacitor electrode 416, which is spaced apart from the first gate electrode 414, is disposed on the first gate insulating layer 412.

A first interlayer insulating layer 418 covering the first gate electrode 414 and the first capacitor electrode 416 is disposed on the first gate insulating layer 412.

A second capacitor electrode 430 corresponding to the first capacitor electrode 416 and a second light shielding pattern 432 spaced apart from the second capacitor electrode 430 are disposed on the first interlayer insulating layer 418.

A second interlayer insulating layer 434 covering the first second capacitor electrode 430 and the second light shielding pattern 432 is disposed on the first interlayer insulating layer 418.

A second semiconductor layer 436 corresponding to the second light shielding pattern 432 is disposed on the second interlayer insulating layer 434. The second semiconductor layer 436 can include one of a poly-semiconductor material, an amorphous semiconductor material and an oxide semiconductor material.

In an example embodiment of the present disclosure, the second semiconductor layer 436 can be formed of an oxide semiconductor material, e.g., indium-gallium-zinc oxide (IGZO), zinc oxide (ZnO), tin oxide (SnO2), copper oxide (Cu2O), nickel oxide (NiO), indium-tin-zinc oxide (ITZO) or indium-aluminum-zinc oxide (IAZO). The second semiconductor layer 436 can include a second channel region 436a, a second source region 436b at one side of the second channel region 436a and a second drain region 436c at the other side of the second channel region 436a. Impurities can be dopped into the second source and drain regions 436b and 436c.

A second gate insulating layer 438 covering the second semiconductor layer 436 is disposed over the second interlayer insulating layer 434.

A second gate electrode 440 corresponding to the second channel region 436a of the second semiconductor layer 436 is disposed on the second gate insulating layer 438.

A third interlayer insulating layer 442 covering the second gate electrode 440 is disposed on the second gate insulating layer 438.

A first source electrode 444a, a first drain electrode 444b, a second source electrode 446a and a second drain electrode 446b are disposed on the third interlayer insulating layer 442.

The first source electrode 444a and the first drain electrode 444b are respectively connected to the first source region 410b and the first drain region 410c via contact holes through the third interlayer insulating layer 442, the second gate insulating layer 438, the second interlayer insulating layer 434, the first interlayer insulating layer 418 and the first gate insulating layer 412. The first source electrode 444a is connected to the first capacitor electrode 416 via a contact hole through the third interlayer insulating layer 442, the second gate insulating layer 438, the second interlayer insulating layer 434 and the first interlayer insulating layer 418.

The second source electrode 446a and the second drain electrode 446b are respectively connected to the second source region 436b and the second drain region 436c via contact holes through the third interlayer insulating layer 442 and the second gate insulating layer 438. The second source electrode 446a is connected to the second capacitor electrode 430 via a contact hole through the third interlayer insulating layer 442, the second gate insulating layer 438 and the second interlayer insulating layer 434.

The first semiconductor layer 410, the first gate electrode 414, the first source electrode 444a and the first drain electrode 444b constitute a first TFT T1, and the second semiconductor layer 436, the second gate electrode 440, the second source electrode 446a and the second drain electrode 446b constitute a second TFT T2. For example, the first TFT T1 can be a switching TFT, and the second TFT can be a driving TFT.

The organic light emitting display device of the present disclosure includes the first and second TFTs T1 and T2. Each of the first semiconductor layer 410 of the first TFT T1 and the second semiconductor layer 436 of the second TFT T2 can include one of a poly-semiconductor material, an amorphous semiconductor material and an oxide semiconductor material, and at least one of the first semiconductor layer 410 of the first TFT T1 and the second semiconductor layer 436 of the second TFT T2 can include the oxide semiconductor material. In an example embodiment of the present disclosure, the first semiconductor layer 410 of the first TFT T1 can be formed of the poly-semiconductor material, e.g., polycrystalline silicon, and the second semiconductor layer 436 of the second TFT T2 can be formed of the oxide semiconductor material.

A planarization layer 450 covering the first source and drain electrodes 444a and 444b and the second source and drain electrodes 446a and 446b is disposed on the third interlayer insulating layer 442. The planarization layer 450 can be formed of an organic insulating material, e.g., photo-aryl or BCB.

The planarization layer 450 can include a first planarization layer 450a on the first source and drain electrodes 444a and 444b and the second source and drain electrodes 446a and 446b, a second planarization layer 450b on the first planarization layer 450a and a third planarization layer 450c on the second planarization layer 450b.

A connection electrode 448 corresponding to the second source electrode 446a is disposed on the first planarization layer 450a. The connection electrode 448 can connected to the second source electrode 446a through a contact hole in the first planarization layer 450a.

The second planarization layer 450b is disposed on the first planarization layer 450a to cover the connection electrode 448, and the third planarization layer 450c is disposed on the second planarization layer 450b. A flatness of an anode 460a of the OLED D can be degraded by a step difference resulting from an electrode or a signal line under the anode 460a so that there can be a problem, e.g., a lifespan decrease of the OLED D. However, in the organic light emitting display device 400 of the present disclosure, the step difference can be compensated by the third planarization layer 450c so that the above problem can be prevented.

In FIG. 7, the planarization layer 450 includes the first to third planarization layers 450a, 450b and 450c to have a triple-layered structure. In an embodiment of the present disclosure, the connection electrode 448 and the first planarization layer 450a can be omitted so that the planarization layer 450 can have a double-layered structure. In an embodiment of the present disclosure, additional planarization layer can be further disposed so that the planarization layer 450 can have four or more layers.

The planarization layer 450 includes a scattering particle. For example, in the planarization layer 450, the scattering particle can be dispersed in an organic insulating material.

In an embodiment of the present disclosure, at least one of the first to third planarization layers 450a, 450b and 450c can include the scattering particle. For example, the second planarization layer 450b can include a first scattering particle 452a and a second scattering particle 452b, and the third planarization layer 450c can include a third scattering particle 454a and a fourth scattering particle 454b.

Each of the first to fourth scattering particles 452a, 452b, 454a and 454b can be formed of an inorganic material, e.g., silicon oxide (SiO2), or an organic material, e.g., polyoxyethylene, polyoxyethylene glycol, polyoxypropylene alkyl ether, polyoxypropylene monoalkyl ether, polyoxypropylene alkyl, polyoxyethylene tallowamine, polyoxyethylene oleylamine, polyoxyethylene sterylamine, polyoxyethylene laurylamine, polyoxyethylene sorbitan ester, polyoxyethylene octyl ether, polyoxyethylene glycerin ether, polyacrylic acid, polysulfonic acid, polyacrylic amine, triethylene amine, their copolymer or their blocked-copolymer.

The first scattering particle 452a has a first diameter (e.g., a size), and the second scattering particle 452b has a second diameter being smaller than the first diameter. The third scattering particle 454a has a third diameter, and the fourth scattering particle 454b has a fourth diameter being smaller than the third diameter.

Each of the first and third scattering particles 452a and 454a can have a diameter in a range of 100 nm to 1000 nm, and each of the second and fourth scattering particles 452b and 454b can have a diameter in a range of 1 nm to 80 nm. For example, each of the first and third scattering particles 452a and 454a can have a diameter in a range of 300 nm to 700 nm, and each of the second and fourth scattering particles 452b and 454b can have a diameter in a range of 10 nm to 70 nm. The diameter of the first scattering particle 452a and the diameter of the third scattering particle 454a can be same or different, and the diameter of the second scattering particle 452b and the diameter of the fourth scattering particle 454b can be same or different. A Mie scattering can occur by each of the first and third scattering particles 452a and 454a, and a Rayleigh scattering can occur by each of the second and fourth scattering particles 452b and 454b.

In the second planarization layer 450b, an amount of the first scattering particle 452a and an amount of the second scattering particle 452b can be same or different. For example, in the second planarization layer 450b, an amount of the first scattering particle 452a can be smaller than an amount of the second scattering particle 452b. In an embodiment of the present disclosure, a ratio of an amount of the first scattering particle 452a to an amount of the second scattering particle 452b can be 1:2.

In the third planarization layer 450c, an amount of the third scattering particle 454a and an amount of the fourth scattering particle 454b can be same or different. For example, in the third planarization layer 450c, an amount of the third scattering particle 454a can be smaller than an amount of the fourth scattering particle 454b. In an embodiment of the present disclosure, a ratio of an amount of the third scattering particle 454a to an amount of the fourth scattering particle 454b can be 1:2.

In FIG. 7, the first planarization layer 450a is formed by an organic insulating material without a scattering particle. Alternatively, the first planarization layer 450a can include a fifth scattering particle and a sixth scattering particle, and a diameter of the fifth scattering particle can be greater than that of the sixth scattering particle. The fifth scattering particle can have a diameter being same or substantially same as at least one of the first and third scattering particle, and the sixth scattering particle can have a diameter being same or substantially same as at least one of the second and fourth scattering particle. For example, the fifth scattering particle can have a diameter in a range of 100 nm to 1000 nm, e.g., 300 nm to 700 nm, and the sixth scattering particle can have a diameter in a range of 1 nm to 80 nm, e.g., 10 nm to 70 nm. Accordingly, a Mie scattering can occur by the fifth scattering particle, and a Rayleigh scattering can occur by the sixth scattering particle.

In FIG. 7, the second planarization layer 450b includes the first and second scattering particles 452a and 452b having different sizes, and the third planarization layer 450c includes the third and fourth scattering particles 454a and 454b having different sizes. In an embodiment of the present disclosure, the second planarization layer 450b includes the first and second scattering particles 452a and 452b having different sizes, and the third planarization layer 450c includes a scattering particle having the same or substantially same size. In an embodiment of the present disclosure, the third planarization layer 450c includes the third and fourth scattering particles 454a and 454b having different sizes, and the second planarization layer 450b includes a scattering particle having the same or substantially same size.

A first electrode 460a is disposed on the second planarization layer 450b. The first electrode 460a corresponds to the connection electrode 448 and is connected to the connection electrode 448 through a contact hole in the second and third planarization layers 450b and 450c.

For example, the first electrode 460a is separately formed in each pixel region P. The first electrode 460a can be an anode and can include a transparent conductive oxide (TCO) layer, which is formed of a conductive material, e.g., a transparent conductive oxide material, having a relatively high work function, and a reflective layer.

For example, the transparent conductive oxide material can include at least one of indium-tin-oxide (ITO), indium-zinc-oxide (IZO), indium-tin-zinc oxide (ITZO), tin oxide (SnO), zinc oxide (ZnO), indium-copper-oxide (ICO) and aluminum-zinc-oxide (Al:ZnO, AZO), and the reflective layer can include at least one of silver (Ag), an alloy of Ag and one of palladium (Pd), Cu, In and Nd and aluminum-palladium-copper alloy (APC). For example, the first electrode 460a can have a double-layered structure of Ag/ITO or APC/ITO or a triple-layered structure of ITO/Ag/ITO or ITO/APC/ITO.

A pixel definition layer 456 is formed on the third planarization layer 450c at a boundary of the pixel region. The pixel definition layer 456 covers an edge of the first electrode 460a and has an opening to expose a center of the first electrode 460a.

The pixel definition layer 456 can have a light-absorbing property. The pixel definition layer 456 can be a black pixel definition layer or a gray pixel definition layer. The pixel definition layer 456 can include a black particle, e.g., a light-absorbing particle, disposed in an organic material, e.g., a binder. For example, the organic material can be at least one of photo-acryl, benzocyclobutene and polyimide, and the black particle can be at least one of carbon black, carbon nano tube (CNT) and graphene.

The pixel definition layer 456 can have a first optical density (OD) of 1.0 or less. For example, the first OD can be in a range of 0.5 to 1.0.

In the organic light emitting display device, after the first electrode 460a is formed, the pixel definition layer 456 covering an edge of the first electrode 460a is formed by coating the organic material including the black particle and performing a mask process. When the pixel definition layer having a relatively high OD, an amount of the black particle in the organic material is increased, and an amount of the organic material is decreased. As a result, a curing process to the organic material is incompletely performed so that a particle can remain on the first electrode 460a. In this case, there can be a problem in a driving voltage and a lifespan of the OLED D.

In the organic light emitting display device 400 of the present disclosure, the above problem can be prevented by decreasing an amount in the pixel definition layer 456 so that the pixel definition layer 456 has a relatively low OD.

When the pixel definition layer 456 has a relatively low OD, an external light (e.g., an ambient light) can pass through the pixel definition layer 456 and be reflected by an electrode and/or a signal line under the pixel definition layer 456 so that the external light reflection can be increased. In addition, the external light passing through the pixel definition layer 456 can be incident to the first semiconductor layer 410 of the first TFT T1 and/or the second semiconductor layer 436 of the second TFT T2 so that the current leakage can occur. For example, when the external light is incident to the first semiconductor layer 410 of the first TFT T1, which is formed of an oxide semiconductor material having a high mobility, the performance of the first TFT T1 can be significantly degraded by the current leakage.

However, in the organic light emitting display device 400 of the present disclosure, the second planarization layer 450b includes the first and second scattering particles 452a and 452b, and the third planarization layer 450c includes the third and fourth scattering particles 454a and 454b. Accordingly, the above problems of the external light reflection and/or the current leakage from the first and second TFTs T1 and T2 can be reduced, prevented or minimized.

In addition, the Mie scattering and the Rayleigh scattering can occur by the first scattering particle 452a and the second scattering particle 452b in the second planarization layer 450b, and the Mie scattering and the Rayleigh scattering can occur by the third scattering particle 454a and the fourth scattering particle 454b in the third planarization layer 450c. As a result, an amount of the light, which passes through the pixel definition layer 456 and is directed to the first and second TFTs T1 and T2 can be reduced or minimized so that the current leakage in the first and second TFTs T1 and T2 by the external light can be reduced, minimized or prevented.

A first spacer 458a having a reverse-tapered shape and a second spacer 458b having a tapered shape are disposed on the pixel definition layer 456.

An organic light emitting layer 460b covering the first electrode 460a, the pixel definition layer 456 and the first and second spacers 458a and 458b is disposed. The organic light emitting layer 460b contacts the first electrode 460a in the opening of the pixel definition layer 456. Namely, the organic light emitting layer 460b can be formed to contact an upper surface of the first electrode 460a, a side surface and an upper surface of the pixel definition layer 456, an upper surface of the first spacer 458a and a side surface and an upper surface of the second spacer 458b.

For example, the organic light emitting layer 460b can include an organic emitting material layer (EML) including a host and a dopant. In addition, the organic light emitting layer 460b can further include at least one of an HIL, an HTL, an EBL, an HBL, an ETL and an EIL to have a multi-layered structure.

A second electrode 460c is formed over the substrate 402 where the organic light emitting layer 460b is formed. The second electrode 460c covers an entire surface of the display area. The second electrode 460c can be formed of at least one of ITO, IZO, Al, Ag, Cu, Pb, magnesium (Mg), Mo, Ti and their alloy and have a single-layered structure or a multi-layered structure. The second electrode 460c can have a thin profile (small thickness) to provide a light transmittance property (or a semi-transmittance property).

The first electrode 460a, the organic light emitting layer 460b and the second electrode 460c constitute an organic light emitting diode D. The organic light emitting diode D can emit the red, green and blue light in the red, green and blue pixel region, respectively. Alternatively, the organic light emitting diode D can emit the with light in the red, green, blue and white pixel regions.

In the organic light emitting display device 400, the light from the light emitting layer 460b passes through the second electrode 460c and a color filter layer 482 to display an image. Namely, the organic light emitting display device 400 of the present disclosure is a top-emission type display device.

An encapsulation layer (or encapsulation film) 462 is formed on the second electrode 460c to prevent penetration of moisture into the organic light emitting diode D. The encapsulation layer 462 can cover an entire substrate 402. The encapsulation layer 462 includes a first inorganic insulating layer 462a, an organic insulating layer 462b and a second inorganic insulating layer 462c sequentially stacked.

A second buffer layer 464 is disposed on the encapsulation layer 462 and over an entire surface of the substrate 402. The moisture and/or oxygen can be blocked by the second buffer layer 464.

A plurality of bridge patterns 466 are disposed on the second buffer layer 464, and a fourth interlayer insulating layer 468 is disposed on the bridge pattern 466 and over an entire surface of the substrate 402.

A sensor pattern 470 is disposed on the fourth interlayer insulating layer 468. The sensor pattern 470 can include a plurality of first sensor patterns 470a, which are spaced apart from each other, and a plurality of second sensor patterns 470b, which are disposed between adjacent first sensor patterns 470a. The first sensor pattern 470a is connected to the bridge pattern 466 through a contact hole in the fourth interlayer insulating layer 468.

A first protection layer 472 is disposed over an entire surface of the substrate 402 to cover the first and second sensor patterns 470a and 470b, and a third buffer layer 474 is disposed on the first protection layer 472 and over an entire surface of the substrate 402.

A black matrix 480 is disposed on the third buffer layer 474. The black matrix 480 is positioned at a boundary of the pixel region P and include an opening in correspond to the organic light emitting diode D. The opening of the black matrix 480 corresponds to the opening of the pixel definition layer 456.

The black matrix 480 has a second OD being greater than the first OD of the pixel definition layer 456. The second OD of the black matrix 480 can be in a range of 0.8 or more. For example, the second OD can be in a range of 0.8 to 1.8.

A size (e.g., a planar area) of the opening in the black matrix 480 can be greater than that of the opening in the pixel definition layer 456. When an opening of the black matrix 480 can be equal to or smaller than an opening of the pixel definition layer 456, a viewing angle of the organic light emitting display device 400 can be decreased.

The black matrix 480 has the opening larger than the opening of the pixel definition layer 456, and the pixel definition layer 456 has a relatively low OD. Accordingly, the external light can pass through the opening of the black matrix 480 and an edge of the pixel definition layer 456 so that there can be a problem of the external light reflection and/or the current leakage from the TFT.

However, as described above, in the organic light emitting display device 400 of the present disclosure, since the planarization layer 450 under the pixel definition layer 456 includes the first to fourth scattering particles 452a, 452b, 454a and 454b, the problem of the external light reflection and the current leakage in the TFTs T1 and T2 caused by the black matrix 480, which includes an opening larger than an opening of the pixel definition layer 456 and the pixel definition layer 456, which has a relatively low OD, can be reduced, prevented or minimized.

In addition, the Mie scattering and the Rayleigh scattering can occur by the first scattering particle 452a and the second scattering particle 452b in the second planarization layer 450b, and the Mie scattering and the Rayleigh scattering can occur by the third scattering particle 454a and the fourth scattering particle 454b in the third planarization layer 450c. Accordingly, an amount of the light toward the TFTs T1 and T2 and an amount of the light toward the pixel definition layer 456 among the light passing through the pixel definition layer 456 to the planarization layer 450 can be reduced or minimized so that the display quality degradation by the external light reflection and the current leakage in the TFTs T1 and T2 can be further reduced or prevented.

A color filter layer 482 corresponding to the black matrix 480 is disposed on the third buffer layer 474. The color filter layer 482 can include a red color filter corresponding to the red pixel region, a green color filter corresponding to the green pixel region and a blue color filter corresponding to the blue pixel region.

Since the organic light emitting display device 400 includes the color filter layer 482, the external light reflection can be reduced or minimized. Namely, since the organic light emitting display device 400 includes the color filter layer 482 without a polarization plate, the external light reflection can be reduced with minimizing the luminance decrease.

A second protection layer 484 is disposed on the black matrix 480 and the color filter layer 482 and over an entire surface of the substrate 402.

In the organic light emitting display device 400 of the present disclosure, the pixel definition layer 456 has a relatively low OD, e.g., a relatively small amount of the black particle, so that a problem resulting from a particle in a fabricating process can be prevented.

In addition, since the planarization layer 450 under the pixel definition layer 456 includes the first to fourth scattering particles 452a, 452b, 454a and 454b, the problem of the external light reflection and the current leakage in the TFTs T1 and T2 can be reduced, prevented or minimized.

Moreover, since the organic light emitting display device 400 includes the color filter layer 482 without a polarization plate, the external light reflection can be reduced with minimizing the luminance decrease.

Furthermore, the Mie scattering and the Rayleigh scattering can occur by the first scattering particle 452a and the second scattering particle 452b in the second planarization layer 450b, and the Mie scattering and the Rayleigh scattering can occur by the third scattering particle 454a and the fourth scattering particle 454b in the third planarization layer 450c. Accordingly, an amount of the light toward the TFTs T1 and T2 and an amount of the light toward the pixel definition layer 456 among the light passing through the pixel definition layer 456 to the planarization layer 450 can be reduced or minimized so that the display quality degradation by the external light reflection and the current leakage in the TFTs T1 and T2 can be further reduced or prevented.

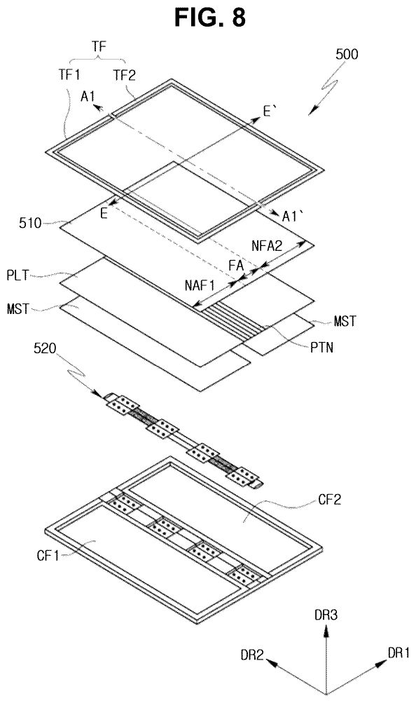

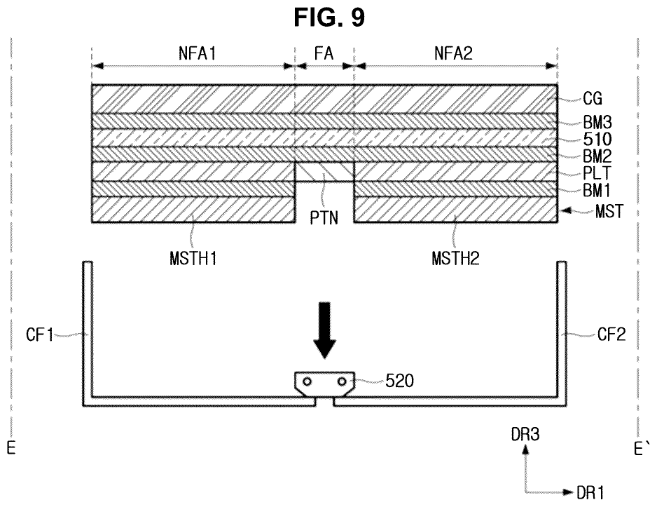

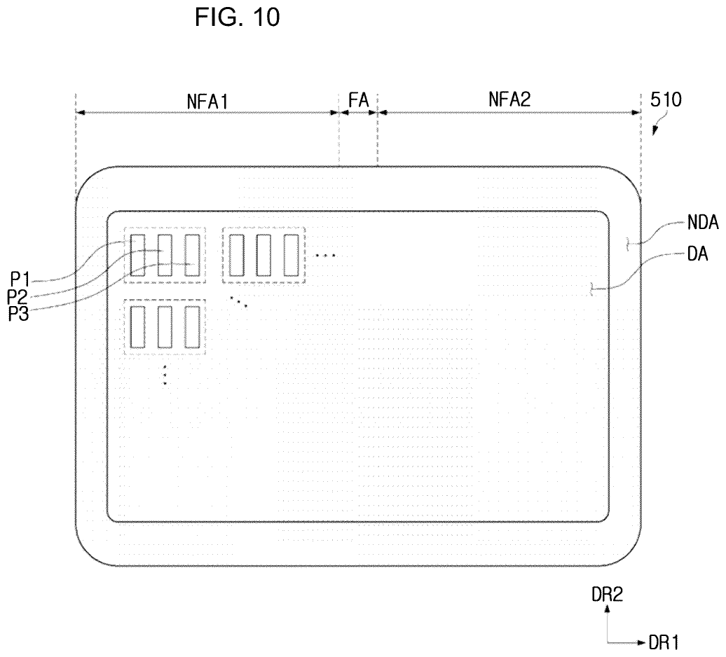

FIG. 8 is a schematic exploded perspective view of a display module according to an embodiment of the present disclosure, FIG. 9 is a schematic cross-sectional view of a display module according to an embodiment of the present disclosure, and FIG. 10 is a schematic plan view of a display module according to an embodiment of the present disclosure. FIG. 9 is a cross-sectional view taken along the line E-E′ in FIG. 8.

Referring to FIGS. 8 to 10, the display module 500 of the present disclosure can be a foldable display device module, and a folding axis A1-A1′ of the display module 500 can be along a second direction DR2. A first direction DR1 can be perpendicular to the second direction DR2, and a third direction DR3 can be perpendicular to the first and second directions DR1 and DR2.

A top frame TF is disposed on the uppermost portion of the display module 500. With respect to the folding axis A1, the top frame TF includes the first top frame TF1 disposed at one side and the second top frame TF2 disposed at the other side. The top frame TF can be disposed to cover an edge of a display device 510. The top frame TF can protect the display device 510 from an external impact. The top frame TFT can form a bezel of the display device 510.

A cover layer CG can be disposed under the top frame TF. The cover layer CG can be disposed above the display device 510.

The cover layer CG can be disposed above the display device 510 to protect members disposed under the cover layer CG from the outside.

An assembly is disposed under the cover layer CG. The assembly includes the display device 510 and a plate PLT. The display device 510 can have substantially the same structure as one of the display devices 100, 200, 300 and 400.

The plate PLT can be disposed under the display device 510 and can include various plates for supporting the display device 510. For example, the plate can include a back plate for supporting the display device 510, a top plate disposed under the back plate and formed of a stainless steel (SUS) material, a bottom plate disposed under the top plate and having a pattern formed on a folding portion, a heat dissipation sheet which functions as heat dissipation, a middle plate for covering an uneven plane due to various elements of the hinge assembly. The bottom plate can be formed of a SUS material.

A slit pattern PTN can be formed in the plate PLT. The slit pattern PTN can be formed at a position corresponding to the folding area FA of the display device 510. The slit pattern PTN can be a slit-shaped etched portion formed in the plate PLT. For example, the plate PLT can be formed of a metal, e.g., a SUS material. In this case, there can be a damage on the plate PLT in the folding operation and/or the unfolding operation. However, in the present application, the plate PLT include the slit pattern PTN so that the above damage on the plate PLT can be prevented.

A middle plate MST is disposed under the assembly. The middle plate MST supports elements disposed thereabove. In addition, the hinge assembly 520 and the cover frame CF are disposed under the middle plate MST, and their upper surfaces can be uneven. The middle plate MST can flatten a uneven lower surface. The middle plate MST can be formed of a material, e.g., plastic, polyimide or metal, to increase the rigidity of the display module 500. For example, the middle plate MST can include aluminum or SUS, but it is not limited thereto.

The middle plate MST can include a first middle plate portion MSTH1 disposed in a first unfolding area NFA1, and a second middle plate portion MSTH2 disposed in a second unfolding area NFA2.

The hinge assembly 520 is disposed under the assembly. The hinge assembly 520 is disposed under the folding area FA. The hinge assembly 520 can have a shape extending in the folding axis A1-A1′. The hinge assembly 520 can perform a folding motion in which one side and the other side rotate about the folding axis A1-A1′.

The cover frame CF is disposed under the hinge assembly 520. An accommodation groove, in which a portion of the hinge assembly 520 can be disposed, can be formed in an upper surface of the cover frame CF. The cover frame CF includes the first cover frame CF1 disposed at one side of the folding axis A1-A1′ and the second cover frame CF2 disposed at the other side of the folding axis A1-A1′. The cover frame CF can be a housing for defining the side and back surfaces of the display module 500. The cover frame CF can protect the display module 500 from an external impact. The cover frame CF can be coupled to the hinge assembly 520. The folding and unfolding of the display module 500 can be provided according to the rotation of the cover frames CF1 and CF2.

Coupling members BM1, BM2, and BM3 for coupling the adjacent members MST, PLT, PNL and CG can be further disposed between the adjacent members. In each of the unfolded areas NFA1 and NFA2, the first coupling member BM1 can couple the middle plates portions MSTH1 and MSTH2 with the plate PLT, and the second coupling member BM2 can couple the plates PLT and PTN with the display device 510. The third coupling member BM3 can couple the display device 510 with the cover layer CG.

The plate PLT, the middle plate MST, and the middle plate MST, which are coupled, can be seated on the cover frames CF1 and CF2. The display device 510 can perform folding and unfolding operations by the hinge assembly 520 disposed on the cover frames CF1 and CF2.

The plate PLT and the middle plate MST, which are coupled to each other, can be disposed on the cover frames CF1 and CF2. The display module 500 can be folded and unfolded by the hinge assembly 520 disposed in the cover frames CF1 and CF2.

The display device 510 can includes a display area DA and a non-display area NDA outside the display area DA. The non-display area NDA can surround the display area DA. In the display area DA, a plurality of pixel regions P1, P2 and P3 are arranged.

The display device 510 can include a folding area FA and a first unfolding area NFA1 at one side of the folding area FA and a second unfolding area NFA2 at the other side of the folding area FA.

It will be apparent to those skilled in the art that various modifications and variations can be made in the embodiments of the present disclosure without departing from the technical idea or scope of the present disclosure. Thus, it is intended that the modifications and variations cover this disclosure provided they come within the scope of the appended claims and their equivalents.

What is claimed is:

1. A display device, comprising:
a substrate including a pixel region;
a thin film transistor on the substrate and in the pixel region;
a planarization layer covering the thin film transistor;
a light emitting diode on the planarization layer and in the pixel region; and
a pixel definition layer at a boundary of the pixel region,
wherein the pixel definition layer has a light-absorbing property, and the planarization layer includes a scattering particle.

2. The display device according to claim 1, wherein the planarization layer includes a first planarization layer and a second planarization layer on the first planarization layer, and
wherein the first planarization layer includes a first scatting particle, and the second planarization layer includes a second scattering particle.

3. The display device according to claim 2, wherein the first and second scattering particles have a same size.

4. The display device according to claim 2, wherein the first and second scattering particles have different sizes.

5. The display device according to claim 2, wherein one of the first and second scattering particles has a diameter in a range of 1 nm to 80 nm, and the other one of the first and second scattering particles has a diameter in a range of 100 nm to 1000 nm.

6. The display device according to claim 2, wherein the planarization layer further includes a third planarization layer under the first planarization layer,
wherein the third planarization layer includes a third scattering particle, and
wherein a size of each of the second and third scattering particles is greater than a size of the first scattering particle.

7. The display device according to claim 2, wherein the planarization layer further includes a third planarization layer under the first planarization layer,
wherein the third planarization layer includes a third scattering particle, and
wherein a size of each of the second and third scattering particles is smaller than a size of the first scattering particle.

8. The display device according to claim 1, wherein the planarization layer includes a first planarization layer and a second planarization layer on the first planarization layer,
wherein the first planarization layer includes a first scattering particle and a second scattering particle, and the second planarization layer includes a third scattering particle and a fourth scattering particle, and
wherein a size of the first scattering particle is larger than a size of the second scattering particle, and a size of the third scattering particle is larger than a size of the fourth scattering particle.

9. The display device according to claim 8, wherein each of the first and third scattering particles has a diameter in a range of 100 nm to 1000 nm, and each of the second and fourth scattering particles has a diameter in a range of 1 nm to 80 nm.

10. The display device according to claim 1, wherein the scattering particle includes a first scattering particle having a diameter in a range of 100 nm to 1000 nm and a second scattering particle having a diameter in a range of 1 nm to 80 nm.

11. The display device according to claim 10, wherein a Rayleigh scattering occurs by the first scattering particle, and a Mie scattering occurs by the second scattering particle.

12. The display device according to claim 1, wherein the thin film transistor includes a semiconductor layer including an oxide semiconductor material.

13. The display device according to claim 1, wherein the thin film transistor includes a first thin film transistor including a first semiconductor layer and a second thin film transistor including a second semiconductor layer, and
wherein at least one of the first and second semiconductor layers includes an oxide semiconductor material.

14. The display device according to claim 1, wherein the thin film transistor includes a first thin film transistor including a first semiconductor layer and a second thin film transistor including a second semiconductor layer, and
wherein one of the first and second thin film transistors includes an oxide semiconductor material, and the other one of the first and second thin film transistor includes a polycrystalline silicon.

15. The display device according to claim 14, wherein the first semiconductor layer includes the oxide semiconductor material, and the first thin film transistor is a driving thin film transistor connected to the light emitting diode.

16. The display device according to claim 1, wherein the pixel definition layer is a black pixel definition layer or a gray pixel definition layer.

17. The display device according to claim 1, further comprising:
an encapsulation layer covering the light emitting diode and the pixel definition layer;
a color filter layer disposed on the encapsulation layer and corresponding to the light emitting diode; and
a black matrix disposed on the encapsulation layer and corresponding to the pixel definition layer.

18. The display device according to claim 17, wherein the black matrix has a first optical density, and the pixel definition layer has a second optical density, and
wherein the second optical density is smaller than the first optical density.

19. The display device according to claim 18, wherein the first optical density has a range of 0.5 to 1.0, and the second optical density has a range of 0.8 to 1.8.

20. The display device according to claim 17, wherein the pixel definition layer includes a first opening corresponding to the light emitting diode, and the black matrix includes a second opening corresponding to the light emitting diode, and
wherein a size of the second opening is larger than a size of the first opening.
